(19) United States
(12) Patent Application Publication
(10) Pub. No.: US 2025/0374503 A1
(43) Pub. Date: Dec. 4, 2025

(54) MEMORY DEVICE AND METHOD OF FORMING SAME

(71) Applicant: Taiwan Semiconductor Manufacturing Company, Ltd., Hsin-Chu (TW)

(72) Inventors: Feng-Ming Chang, Zhubei City (TW); Jui-Lin Chen, Taipei City (TW)

(21) Appl. No.: 19/287,357

(22) Filed: Jul. 31, 2025

Related U.S. Application Data
(63) Continuation of application No. 18/919,673, filed on Oct. 18, 2024.
(60) Provisional application No. 63/652,956, filed on May 29, 2024.

(51) Int. Cl. H10B 10/00; G11C 11/412; G11C 11/419; H10D 30/01; H10D 30/43; H10D 30/67; H10D 62/10; H10D 62/13; H10D 64/01; H10D 64/23; H10D 84/01; H10D 84/03; H10D 84/83

(52) U.S. Cl. CPC H10B 10/12; G11C 11/412; G11C 11/419; H10D 30/014; H10D 30/43; H10D 30/6735; H10D 30/6757; H10D 62/121; H10D 62/151; H10D 64/017; H10D 64/251; H10D 84/013; H10D 84/0135; H10D 84/0149; H10D 84/038; H10D 84/83

(57) ABSTRACT

A method of manufacturing a semiconductor device includes forming a stack that includes channel layers interleaved by sacrificial layers, patterning the stack to form a fin-shaped structure, forming a dummy gate stack across the fin-shaped structure, selectively removing the sacrificial layers to release the channel layers as channel members, depositing a dummy layer in space between the channel members, removing the dummy gate stack, removing the dummy layer, forming a gate structure to wrap around each of the channel members, depositing a backside dielectric layer on a backside of the semiconductor device, patterning the backside dielectric layer to form a backside gate via opening directly under the gate structure, doping a threshold voltage tuning dopant into the gate structure through the backside gate via opening, and after the doping of the threshold voltage tuning dopant, forming a backside gate via in the backside gate via opening.

### PRIORITY DATA

This is a continuation application of U.S. patent application Ser. No. 18/919,673, field Oct. 18, 2024, which claims benefit of U.S. Provisional Patent Application No. 63/652,956, filed May 29, 2024, each of which is incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

In deep sub-micron integrated circuit technology, static random-access memory (SRAM) device has become a popular storage unit for high-speed communication, image processing, and system-on-chip (SOC) products. The number of embedded SRAM devices in microprocessors and SOCs continues to increase to meet the performance demands of each new technology generation. As silicon technology scales with each successive generation, fabrication of SRAM devices faces certain limitations. For example, SRAM devices may encounter issues raised from low cell ratio problems, such as a low beta ratio. The beta ratio is the ratio of the drive current of pull-down transistors to the drive current of the respective pass-gate transistors. The beta ratio is important for the SRAM cell stability. Generally, a beta ratio greater than 1 provides a larger operational window during read operations. In the formation of high-density SRAM arrays, however, having a beta ratio greater than 1 presents challenges in a manufacturing flow. For example, it is difficult to meet this requirement while at the same time keep the cell size small.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B illustrate a perspective view and a top view of a portion of a memory device, respectively, in accordance with some embodiments of the present disclosure.

FIG. 2 illustrates a cross-sectional view of various layers of a memory device, in accordance with some embodiments of the present disclosure.

FIG. 3 illustrates a circuit schematic of a static random-access memory (SRAM) cell, in accordance with some embodiments of the present disclosure.

FIG. 4 illustrates a layout of the SRAM cell as in FIG. 3, in accordance with some embodiments of the present disclosure.

FIGS. 5 and 6 illustrate layouts of frontside features of a 2×2 SRAM array, in accordance with some embodiments of the present disclosure.

FIGS. 7 and 8 illustrate layouts of backside features of a 2×2 SRAM array, in accordance with some embodiments of the present disclosure.

FIG. 9 shows a flow chart of a method for forming an integrated circuit having a plurality of SRAM cells, in accordance with some embodiments of the present disclosure.

FIGS. 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, and 44 illustrate cross-sectional views of an integrated circuit having SRAM cells during fabrication processes according to the method of FIG. 9, in accordance with some embodiments of the present disclosure.

FIGS. 45, 46, 47, and 48 illustrate plots of a threshold tuning dopant concentration in a gate structure of pass-gate transistors in SRAM cells, in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

The present disclosure provides various embodiments of a memory device. Particularly, the present disclosure provides various embodiments of a static-random-access memory (SRAM) device structure with a beta ratio greater than 1. The term “beta ratio” is defined as the ratio of the drive current of pull-down transistors and the drive current of the respective pass-gate transistors in an SRAM cell. The beta ratio is an important parameter regarding SRAM cell stability. The beta ratio affects the stability of an SRAM cell. The beta ratio being greater than 1 implies that the pull-down transistors are stronger than the pass-gate transistors, which ensures that during a read operation the stored data is not inadvertently flipped. The beta ratio being greater than 1 also improves static noise margin (SNM) during a read operation and increases the maximum voltage level (Vmax) at which the storage node of an SRAM cell can rise during a read operation.

In some implementations, an SRAM cell comprises the pull-down transistors and pass-gate transistors formed of a same type of transistors with the same dimensions of the active regions and the same material compositions of the work functional metal (WFM) layer in the gate structures. Thus, the pull-down transistors and pull-up transistors in the same SRAM cell would have the same threshold voltage (Vt) and the same current drive capability, resulting in the beta ratio equal to 1. However, the aggressive scaling down of IC dimensions has led to densely spaced active regions and gate structures, making it challenging to vary the dimensions of the active regions and the material compositions of the WFM layer in the gate structures for different transistors.

In the embodiments of the present disclosure, the threshold voltage of the pass-gate transistors is separately adjusted by doping threshold voltage (Vt) tuning dopants into the WFM layer in the gate structures of the pass-gate transistors during the formation of gate vias. The Vt tuning dopants increase the threshold voltage of the pass-gate transistors and decrease their current drive capability relative to the pull-down transistors, and accordingly increasing the beta ratio. The introduction of the Vt tuning dopants is performed up until the gate via formation step, ensuring that the front-end-of-line (FEOL) process, which involves the formation of the transistor structures, remains unaltered.

The gate vias on the pass-gate transistors provide electrical connections between the gate structures and word lines in the multilayer interconnect structure. In SRAM devices, multilayer interconnect structure is formed over source/drain contacts and gate vias of the transistors of the memory cells. The multilayer interconnect structure provides metal routings for interconnecting power lines and signal lines (such as bit lines and word lines) in and between memory cells of SRAM devices. With the continued downscaling of SRAM devices, the metal lines in the multilayer interconnect structure also undergo reduction. As the available layout arca becomes more limited, the metal lines are formed with reduced dimensions, which leads to increased voltage drops. One solution is to form metal lines on the backside of SRAM cells in addition to the frontside, thereby reducing routing density. The multilayer interconnect structures formed on both the frontside and backside of SRAM cells are referred to as dual-side multilayer interconnect structures. Consequently, gate vias may be formed on the frontside, backside, or both sides of the SRAM cells. Those gate vias formed on the gate structures of the pass-gate transistors provide an opportunity in the manufacturing process to further adjust the threshold voltages of the pass-gate transistors and increase the beta ratio of SRAM cells.

The details of the device structures disclosed herein are described with reference to the accompanying figures. Some exemplary embodiments are related to, but not otherwise limited to, multi-gate transistors. Multi-gate transistors have been introduced in an effort to improve gate control by increasing gate-channel coupling, reduce OFF-state current, and reduce short-channel effects (SCEs). One such multi-gate transistor that has been introduced is the fin-like field-effect transistor (FinFET). The FinFET gets its name from the fin-like structure which extends from a substrate on which it is formed, and which is used to form the FET channel. Another multi-gate transistor, introduced in part to address performance challenges associated with the FinFET, is the gate-all-around (GAA) transistor. The GAA transistor gets its name from the gate structure which can extend around the channel region (e.g., a stack of channel members) providing access to the channel on four sides. The GAA transistor is compatible with conventional complementary metal-oxide-semiconductor (CMOS) processes and its structure allows it to be aggressively scaled while maintaining gate control and mitigating SCEs. The following disclosure will continue with one or more GAA examples to illustrate various embodiments of the present disclosure. It is understood, however, that the application should not be limited to a particular type of device, except as specifically claimed. For example, aspects of the present disclosure may also apply to implementation based on FinFETs or planar FETs.

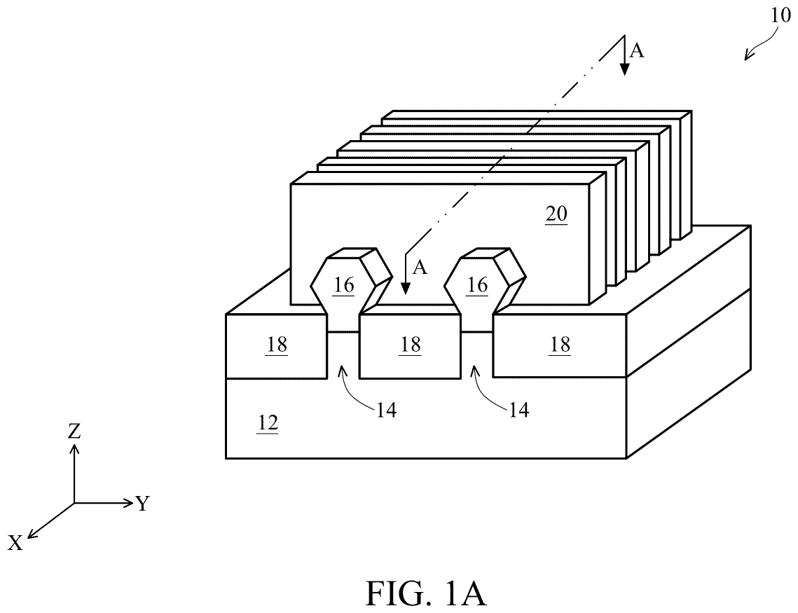

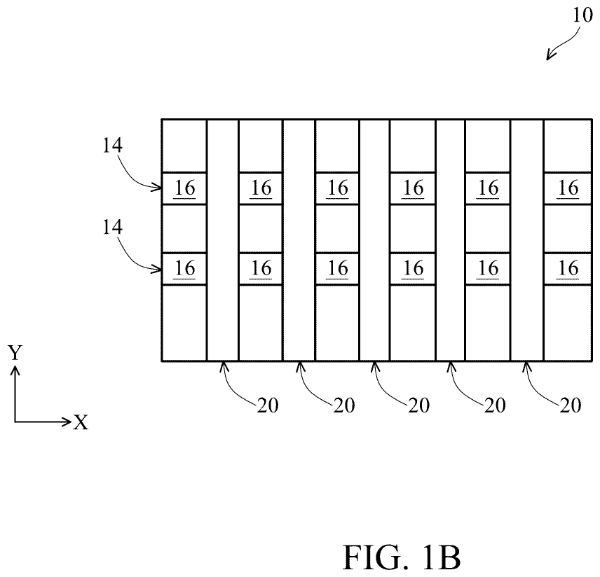

FIGS. 1A and IB illustrate a perspective view and a top view, respectively, of a portion of an Integrated Circuit (IC) device 10, such as an SRAM device, implemented using multi-gate transistors, such as GAA transistors. Referring to FIG. 1A, the IC device 10 includes a substrate 12. The substrate 12 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 12 may be a single-layer material having a uniform composition. Alternatively, the substrate 12 may include multiple material layers having similar or different compositions suitable for IC device manufacturing. In one example, the substrate 12 may be a silicon-on-insulator (SOI) substrate having a semiconductor silicon layer formed on a silicon oxide layer. In another example, the substrate 12 may include a conductive layer, a semiconductor layer, a dielectric layer, other layers, or combinations thereof. Various doped regions, such as source/drain regions, may be formed in or on the substrate 12. The doped regions may be doped with n-type dopants, such as phosphorus or arsenic, and/or p-type dopants, such as boron, depending on design requirements. The doped regions may be formed directly on the substrate 12, in a p-well structure, in an n-well structure, in a dual-well structure, or using a raised structure. Doped regions may be formed by implantation of dopant atoms, in-situ doped epitaxial growth, and/or other suitable techniques.

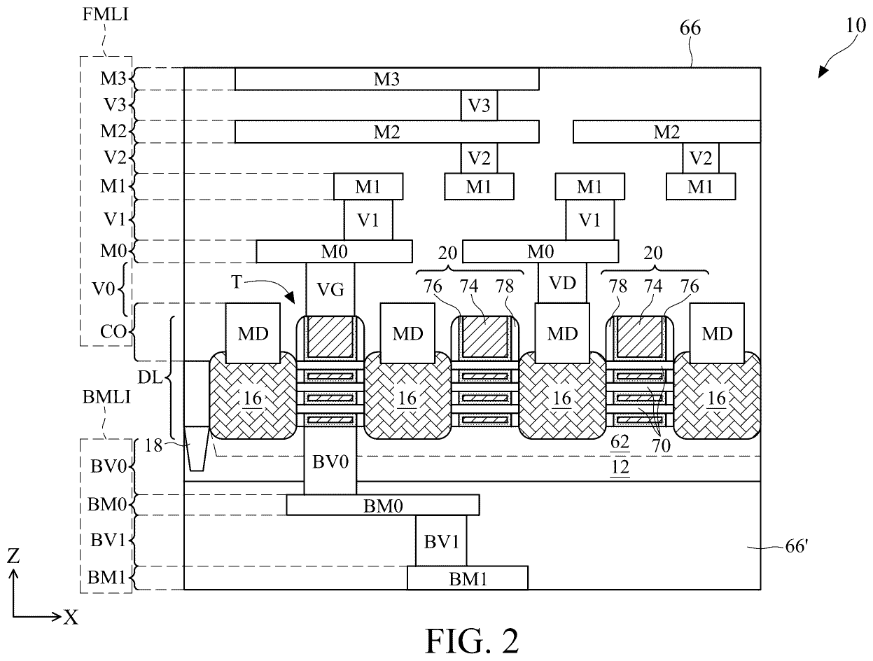

Three-dimensional active regions 14 are formed on the substrate 12. An active region for a transistor refers to the area where a source region, a drain region, and a channel region under a gate structure of the transistor are formed. An active region is also referred to as an “oxide-definition (OD) region” in the context. Each of the active regions 14 includes elongated nanostructures 70 (as shown in FIG. 2) vertically stacked in channel regions defined in the active region and above a fin-shape base. The fin-shape base protrudes upwardly out of the substrate 12. Source/drain features 16 are formed in source/drain regions defined in the active region and over the fin-shape base. The source/drain features 16 abut two opposing ends of the nanostructures 70. The source/drain features 16 may include epi-layers that are epitaxially grown on the fin-shape base.

The IC device 10 further includes isolation structures (or isolation features) 18 formed over the substrate 12. The isolation structures 18 electrically separate various components of the IC device 10. The isolation structures 18 may include silicon oxide, silicon nitride, silicon oxynitride, fluoride-doped silicate glass (FSG), a low-k dielectric material, and/or other suitable materials. In some embodiments, the isolation structures 18 may include shallow trench isolation (STI) features. In one embodiment, the isolation structures 18 are formed by etching trenches in the substrate 12 during the formation of the active regions 14. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 18. Alternatively, the isolation structures 18 may include a multi-layer structure, for example, having one or more thermal oxide liner layers.

The IC device 10 also includes gate structures (or gate stacks) 20 formed over and engaging channel regions in the active regions 14. The gate structures 20 may be dummy gate structures (e.g., containing an oxide gate dielectric and a polysilicon gate electrode), or they may be high-k metal gate (HKMG) structures that contain a high-k gate dielectric and a metal gate electrode, where the HKMG structures are formed by replacing the dummy gate structures. Though not depicted herein, the gate structures 20 may include additional material layers, such as an interfacial layer, a capping layer, other suitable layers, or combinations thereof.

Referring to FIG. 1B, multiple active regions 14 are oriented lengthwise along the X-direction, and multiple gate structures 20 are oriented lengthwise along the Y-direction, i.e., generally perpendicular to the active regions 14. At intersections of the active regions 14 and the gate structures 20, transistors are formed. In many embodiments, the IC device 10 includes additional features such as gate spacers disposed along sidewalls of the gate structures 20, and numerous other features.

FIG. 2 is a fragmentary diagrammatic cross-sectional view of various layers (levels) that can be fabricated over and under a semiconductor substrate (or wafer) to form a portion of a memory device, such as IC chip 10 of FIGS. 1A and 1B, according to various aspects of the present disclosure. As represented in FIG. 2, the various layers include a device layer DL, a frontside multilayer interconnect structure FMLI disposed over the device layer DL, and a backside multilayer interconnect structure BMLI disposed under the device layer DL.

Device layer DL includes devices (e.g., transistors, resistors, capacitors, and/or inductors) and/or device components (e.g., doped wells, gate structures, and/or source/drain features). In embodiments represented by FIG. 2, the device layer DL includes substrate 12, doped regions 62 (e.g., n-wells and/or p-wells) disposed in substrate 12, isolation feature 18, and transistors T. In the depicted embodiment, transistors T include suspended channel layers (also referred to as channel members) 70 in the form of nanostructures (e.g., nanowires or nanosheets) and gate structures 20 disposed between source/drain features 16, where gate structures 20 wrap and/or surround suspended channel layers 70. Each gate structure 20 has a metal gate stack formed from a gate electrode 74 disposed over a gate dielectric layer 76, together with gate spacers 78 disposed along sidewalls of the metal gate stack.

Multilayer interconnect structures FMLI and BMLI electrically couple various devices and/or components of device layer DL, such that the various devices and/or components can operate as specified by design requirements for the memory device. Each of the multilayer interconnect structures FMLI and BMLI may include one or more interconnect layers.

In the depicted embodiment, the frontside multilayer interconnect structure FMLI includes a contact interconnect layer (CO level), a via zero interconnect layer (V0 level), a metal zero interconnect layer (M0 level), a via one interconnect layer (V1 level), a metal one interconnect layer (M1 level), a via two interconnect layer (V2 level), a metal two interconnect layer (M2 level), a via three interconnect layer (V3 level), and a metal three interconnect layer (M3 level). Each of the CO level, V0 level, M0 level, V1 level, M1 level, V2 Level, M2 level, V3 level, and M3 level may be referred to as a metal level. Metal lines formed at the M0 level may be referred to as M0 metal lines. Similarly, via or metal lines formed at the V1 level, M1 level, V2 level, M2 level, V3 level, and M3 level may be referred to as V1 vias, M1 metal lines, V2 vias, M2 metal lines, V3 vias, and M3 metal lines, respectively. The present disclosure contemplates multilayer interconnect structure FMLI having more or less interconnect layers and/or levels, for example, a total number of N interconnect layers (levels) of the multilayer interconnect structure FMLI with N as an integer ranging from 1 to 10. Each level of multilayer interconnect structure FMLI includes conductive features (e.g., metal lines, metal vias, and/or metal contacts) disposed in one or more dielectric layers (e.g., an interlayer dielectric (ILD) layer and an etch stop layer (ESL)). The dielectric layers of the multilayer interconnect structure FMLI are collectively referred to as a dielectric structure 66. In some embodiments, conductive features at a same level of multilayer interconnect structure FMLI, such as M0 level, are formed simultaneously. In some embodiments, conductive features at a same level of multilayer interconnect structure FMLI have top surfaces that are substantially planar with one another and/or bottom surfaces that are substantially planar with one another.

In the depicted embodiment, the CO level includes source/drain contacts MD disposed in the dielectric structure 66. The source/drain contacts MD may be formed on and in direct contact with silicide layers disposed directly on the source/drain features 16. The V0 level includes gate vias VG disposed on the gate structures and source/drain contact vias VD disposed on the source/drain contacts MD, where gate vias VG connect gate structures to M0 metal lines, source/drain vias V0 connect source/drain contacts MD to M0 metal lines. In some embodiments, the V0 level may also include butted contacts disposed in the dielectric structure 66. The V1 level includes V1 vias disposed in the dielectric structure 66, where V1 vias connect M0 metal lines to M1 metal lines. M1 level includes M1 metal lines disposed in the dielectric structure 66. V2 level includes V2 vias disposed in the dielectric structure 66, where V2 vias connect M1 metal lines to M2 metal lines. M2 level includes M2 metal lines disposed in the dielectric structure 66. V3 level includes V3 vias disposed in the dielectric structure 66, where V3 vias connect M2 metal lines to M3 metal lines.

In the depicted embodiment, the backside multilayer interconnect structure BMLI includes a backside via zero interconnect layer (BV0 level), a backside metal zero level (BM0 level), a backside via one interconnect layer (BV1 level) and a backside metal one interconnect layer (BM1 level). Each of the BV0 level, BM0 level, BV1 level, and BM1 level may be referred to as a metal level. Metal lines formed at the BM0 level may be referred to as BM0 metal lines. Similarly, via or metal lines formed at the BV0 level, BV1 level, and BM1 level may be referred to as BV0 vias, BV1 vias, and BM1 metal lines, respectively. The present disclosure contemplates multilayer interconnect structure BMLI having more or less interconnect layers and/or levels, for example, a total number of M interconnect layers (levels) of the multilayer interconnect structure BMLI with M as an integer ranging from 1 to 10. Each level of multilayer interconnect structure BMLI includes conductive features (e.g., metal lines, metal vias, and/or metal contacts) disposed in one or more dielectric layers (e.g., an interlayer dielectric (ILD) layer and an etch stop layer (ESL)). The dielectric layers of the multilayer interconnect structure BMLI are collectively referred to as a backside dielectric structure 66′. In some embodiments, conductive features at a same level of the backside multilayer interconnect structure BMLI, such as BM0 level, are formed simultaneously. In some embodiments, conductive features at a same level of multilayer interconnect structure BMLI have top surfaces that are substantially planar with one another and/or bottom surfaces that are substantially planar with one another.

In the depicted embodiment, the BV0 level includes vias BV0 formed under the device layer DL. For example, the vias BV0 may include one or more backside gate vias formed directly under and in direct contact with the gate structure(s) of the device layer DL. The vias BV0 may also include one or more backside source/drain vias formed directly under the source/drain features of the device layer DL and coupled to those source/drain features by way of a silicide layer. The BM0 level includes BM0 metal lines formed under the BV0 level. The backside gate vias connect gate structures to BM0 metal lines, and the backside source/drain vias connect source/drain features to BM0 metal lines. The BV1 level includes BV1 vias disposed in the backside dielectric structure 66′, where BV1 vias connect BM0 metal lines to BM1 metal lines. The BM1 level includes BM1 metal lines formed under the BV1 level.

FIG. 2 has been simplified for the sake of clarity to better understand the inventive concepts of the present disclosure. Additional features can be added in the various layers of the memory, and some of the features described can be replaced, modified, or eliminated in other embodiments of the memory. FIG. 2 is merely an example and may not reflect an actual cross-sectional view of the IC chip 10 and/or the SRAM cells 100 that are described in further detail below.

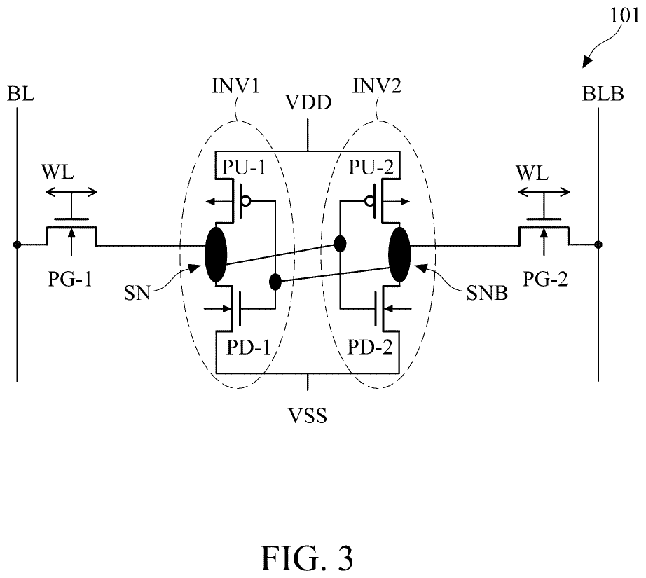

Referring now to FIG. 3, an exemplary circuit diagram for an SRAM cell 100 is shown. The SRAM cell 100 includes two inverters cross-coupled together to store a bit of data and further includes a pass gate electrically connected to the two inverters for reading from and write into the SRAM cell. FIG. 3 has been simplified for the sake of clarity to better understand the inventive concepts of the present disclosure. Additional features can be added in the SRAM cell 104, and some of the features described below can be replaced, modified, or eliminated in other embodiments of the SRAM cell 100.

The exemplary SRAM cell 100 includes six transistors: a pass-gate transistor PG-1, a pass-gate transistor PG-2, a pull-up transistor PU-1, a pull-up transistor PU-2, a pull-down transistor PD-1, and a pull-down transistor PD-1. The exemplary SRAM cell 100 is thus referred to as a 6-transistor (6-T) SRAM cell. The 6-T SRAM cell is used for illustration and to explain the features, but does not limit the embodiments or the appended claims. This non-limiting embodiment may be further extended to SRAM cells comprising more than six transistors, such as an 8-T SRAM cell, a 10-T SRAM cell, and to content addressable memory (CAM) cells.

Further, the exemplary SRAM cell 100 is a single-port SRAM cell that includes a write- port, which is used for illustration and to explain the features, but does not limit the embodiments or the appended claims. This non-limiting embodiment may be further extended to a multi-port SRAM cell, such as a two-port SRAM cell that includes a write-port and a read-port.

In operation, the pass-gate transistors PG-1, PG-2 provide access to a storage portion of the SRAM cell 100, which includes a cross-coupled pair of inverters, a first inverter INV1 and a second inverter INV2. The first inverter INV1 includes the pull-up transistor PU-1 and the pull-down transistor PD-1, and the second inverter INV2 includes the pull-up transistor PU-2 and the pull-down transistor PD-2.

A gate of the pull-up transistor PU-1 interposes a source (electrically coupled with a power voltage line or referred to as a VDD line) and a first common drain (CD1), and a gate of the pull-down transistor PD-1 interposes a source (electrically coupled with an electrical ground line or referred to as a VSS line) and the first common drain (CD1). A gate of the pull-up transistor PU-2 interposes a source (electrically coupled with the VDD line) and a second common drain (CD2), and a gate of the pull-down transistor PD-2 interposes a source (electrically coupled with the VSS line) and the second common drain (CD2). In some implementations, the first common drain (CD1) is a storage node (SN) that stores data in true form, and the second common drain (CD2) is a storage node (SNB) that stores data in complementary form. The gate of the pull-up transistor PU-1 and the gate of the pull-down transistor PD-1 are coupled with the second common drain (CD2), and the gate of the pull-up transistor PU-2 and the gate of the pull-down transistor PD-2 are coupled with the first common drain (CD1). A gate of the pass-gate transistor PG-1 interposes a source (electrically coupled with a bit line BL) and a drain, which is electrically coupled with the first common drain (CD1). A gate of the pass-gate transistor PG-2 interposes a source (electrically coupled with a complementary bit line BLB) and a drain, which is electrically coupled with the second common drain (CD2). The gates of the pass-gate transistors PG-1, PG-2 are electrically coupled with a word line WL. In some implementations, pass-gate transistors PG-1, PG-2 provide access to storage nodes SN, SNB during read operations and/or write operations. For example, the pass-gate transistors PG-1, PG-2 couple storage nodes SN, SNB respectively to bit lines BL, BLB in response to voltage applied to the gates of pass-gate transistors PG-1, PG-2 by the word lines WLs.

When the SRAM cell 100 is read from, a positive voltage is placed on the word line WL, and the pass gate transistors PG-1 and PG-2 allow the bit lines BL and BLB to be coupled to, and receive the data from, the storage nodes SN and SNB. Unlike a dynamic memory or DRAM cell, a SRAM cell does not lose its stored state during a read, so no data “write back” operation is required after a read. The bit lines BL and BLB form a complementary pair of data lines. As is known to those skilled in the art, these paired data lines may be coupled to a differential sense amplifier (not shown); and the differential voltage read from SRAM cells can be sensed and amplified. The amplified sensed signal, which is at a logic level voltage, may then be output as read data to other logic circuitry in the device.

In some embodiments, the pull-up transistors PU-1, PU-2 are configured as p-type field-effect transistors (PFETs), and the pull-down transistors PD-1, PD-2 are configured as n-type filed-effect transistors (NFETs). In some implementations, the pass-gate transistors PG-1, PG-2 are also configured as NFETs. Various NFETs and PFETs may be formed by any proper technology, such as fin-like FETs (FinFETs) or gate-all-around (GAA) FETs.

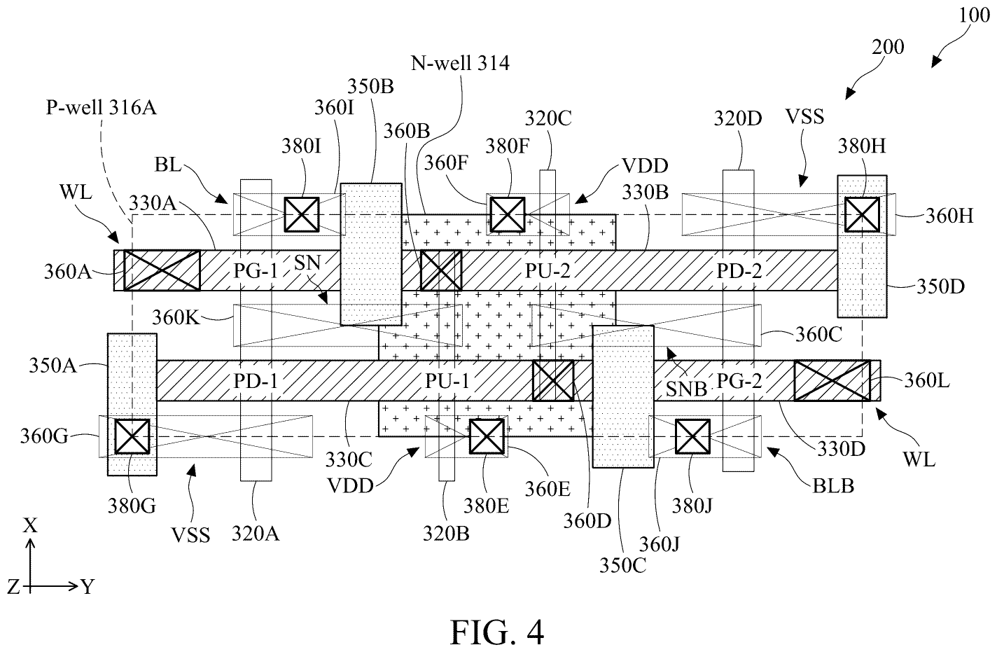

FIG. 4 illustrates a layout 200 of the SRAM cell 100 (represented by a dashed box), of which the circuit diagram is shown in FIG. 3, according to various aspects of the present disclosure. FIG. 4 has been simplified for the sake of clarity to better understand the inventive concepts of the present disclosure. For example, for convenience of illustration, the simplified layout 200 shown in FIG. 4 illustrates, among other features, a layout of wells, active regions, gate structures, source/drain contacts formed on source/drain regions, gate contacts formed on gate structures, and gate isolation features in cut-metal-gate (CMG) trenches that “cut” an otherwise continuous gate structure into multiple segments. Source/drain region(s) may refer to a source or a drain, individually or collectively dependent upon the context. One of ordinary skill in the art should also understand that for the purpose of illustration, FIG. 4 only shows one exemplary configuration of a layout of a 6-T SRAM bit cell. Additional features can be added in the layout 200, and some of the features described below can be replaced, modified, or eliminated corresponding to other embodiments of the SRAM cell 100.

Still referring to FIG. 4, the SRAM cell 100 includes six transistors: a pass-gate transistor PG-1, a pass-gate transistor PG-2, a pull-up transistor PU-1, a pull-up transistor PU-2, a pull-down transistor PD-1, and a pull-down transistor PD-1. The layout 200 thus represents a layout of a 6-T SRAM cell. The SRAM cell 100 includes a region 314 that provides an n-well between a region 316A and a region 316B that each provides a p-well (collectively as region 316). The pull-up transistors PU-1, PU-2 are disposed over the region 314; the pull-down transistor PD-1 and the pass-gate transistor PG-1 are disposed over the region 316A; and the pull-down transistor PD-2 and the pass-gate transistor PG-2 are disposed over the region 316B. In some implementations, the pull-up transistors PU-1, PU-2 are configured as PFETs, and the pull-down transistors PD-1, PD-2 and the pass-gate transistors PG-1, PG-2 are configured as NFETs.

Each of the transistors PG-1, PG-2, PU-1, PU-2, PD-1, and PD-2 includes an active region. In the illustrated embodiment, the SRAM cell 100 includes active regions 320A, 320B, 320C, and 320D (collectively, as the active regions 320) disposed over a semiconductor substrate. The active regions 320 are extending lengthwise in the X-direction and oriented substantially parallel to one another. In some implementations, the active regions 320 are a portion of the semiconductor substrate (such as a portion of a material layer of the semiconductor substrate). For example, where the semiconductor substrate includes silicon, the active regions 320 include fins and project upwardly and continuously from the semiconductor substrate, and the transistors PG-1, PG-2, PU-1, PU-2, PD-1, and PD-2 are FinFET transistors. Alternatively, in some implementations, the active regions 320 are defined in one or more semiconductor material layers, overlying the semiconductor substrate. For example, the active regions 320 can include a stack of nanostructures (nanowires or nanosheets) vertically stacked over the semiconductor substrate, and the transistors PG-1, PG-2, PU-1, PU-2, PD-1, and PD-2 are GAA transistors.

Different active regions in different transistors of the SRAM cell 100 may have the same width or different widths (e.g., dimensions measured in the Y-direction) in order to optimize device performance. In the depicted embodiment, the active region 320A of the PD-1 transistor and the PG-1 transistor and the active region 320D of the PD-2 transistor and the PG-2 transistor have a first width, the active region 320B of the PU-1 transistor and the active region 320C have a second width that is smaller than the first width. The first and second widths are measured in the portions of the respective active regions underneath the gate structures 330. In other words, these portions of the active regions (from which the first and second widths are measured) are the channel regions (e.g., the vertically-stacked nanostructures of GAA devices) of the transistors. Since the PG-1 transistor and the PD-1 transistor (as well as the PG-2 transistor and the PD-2 transistor) are formed on the same active region, these two transistors have the same channel width. If the work functional metal in the gate structures 330 are also the same, the PG-1 transistor and the PD-1 transistor (as well as the PG-2 transistor and the PD-2 transistor) would have substantially the same threshold voltage (Vt) and current drive capabilities. Consequently, the beta ratio would be equal to 1. How to separately adjust the work functional metal in the respective gate structure of the PG-1 transistor (as well as the PG-2 transistor) to achieve the beta ratio being greater than 1 is further described below in detail.

Various gate structures (or referred to as gate stacks, or simply as gates) are disposed over the active regions 320, such as gate structures 330A, 330B, 330C, and 330D (collectively, as the gate structures 330). The gate structures 330 extend lengthwise along the Y-direction (for example, substantially perpendicular to the active regions 320). The gate structures 330 wrap at least portions of the active regions 320, positioned such that the gate structures interpose respective source/drain regions of the active regions 320. The gate structure 330A is disposed over the active region 320A; the gate structure 330C is disposed over the active regions 320A, 320B, 320C; the gate structure 330B is disposed over the active regions 320B, 320C, 320D; and the gate structure 330D is disposed over the active region 320D. A gate of the pass-gate transistor PG-1 is formed from the gate structure 330A, a gate of the pull-down transistor PD-1 is formed from the gate structure 330C, a gate of the pull-up transistor PU-1 is formed from the gate structure 330C, a gate of the pull-up transistor PU-2 is formed from the gate structure 330B, a gate of the pull-down transistor PD-2 is formed from the gate structure 330B, and a gate of the pass-gate transistor PG-2 is formed from the gate structure 330D.

A gate via 360A (or referred to gate contact 360A) electrically connects a gate of the pass-gate transistor PG-1 (formed by gate structure 330A) to a word line WL, and a gate via 360L (or referred to gate contact 360L) electrically connects a gate of the pass-gate transistor PG-2 (formed by gate structure 330D) to the word line WL. A source/drain contact 360K electrically connects a drain region of the pull-down transistor PD-1 (formed on the active region 320A (which may include n-type epitaxial source/drain features)) and a drain region of the pull-up transistor PU-1 (formed on the active region 320B (which may include p-type epitaxial source/drain features)), such that a common drain of pull-down transistor PD-1 and pull-up transistor PU-1 form a storage node SN. A gate via 360B (or referred to as gate contact 360B) electrically connects a gate of the pull-up transistor PU-2 (formed by gate structure 330B) and a gate of the pull-down transistor PD-2 (also formed by gate structure 330B) to the storage node SN. A source/drain contact 360C electrically connects a drain region of the pull-down transistor PD-2 (formed on the active region 320D (which may include n-type epitaxial source/drain features)) and a drain region of the pull-up transistor PU-2 (formed on the active region 320C (which may include p-type epitaxial source/drain features)), such that a common drain of pull-down transistor PD-2 and pull-up transistor PU-2 form a storage node SNB. A gate via 360D (or referred to as gate contact 360D) electrically connects a gate of the pull-up transistor PU-1 (formed by the gate structure 330C) and a gate of the pull-down transistor PD-1 (also formed by the gate structure 330C) to the storage node SNB.

A source/drain contact 360E and a source/drain contact via 380E landing thereon electrically connects a source region of pull-up transistor PU-1 (formed on the active region 320B (which can include p-type epitaxial source/drain features)) to a power supply voltage VDD, and a source/drain contact 360F and a source/drain contact via 380F landing thereon electrically connects a source region of the pull-up transistor PU-2 (formed on the active region 320C (which may include p-type epitaxial source/drain features)) to the power supply voltage VDD. A source/drain contact 360G and a source/drain contact via 380G landing thereon electrically connects a source region of the pull-down transistor PD-1 (formed on the active region 320A (which may include n-type epitaxial source/drain features)) to a grounding voltage VSS, and a source/drain contact 360H and a source/drain contact via 380H electrically connects a source region of the pull-down transistor PD-2 (formed on the active region 320D (which may include n-type epitaxial source/drain features)) to the grounding voltage VSS. The source/drain contact 360G, source/drain contact via 380G, the source/drain contact 360H, and source/drain contact via 380H may be device-level contacts and contact vias that are shared by adjacent SRAM cells 100 (e.g., four SRAM cells 100 abutting at a same corner may share one source/drain contact 360G and one source/drain contact via 380G landing thereon). A source/drain contact 360I electrically connects a source region of the pass-gate transistor PG-1 (formed on the fin 320A (which may include n-type epitaxial source/drain features)) to a bit line BL, and a source/drain contact 360J electrically connects a source region of the pass-gate transistor PG-2 (formed on the fin 320D (which may include n-type epitaxial source/drain features)) to a complementary bit line BLB. In the context, a source/drain contact electrically connecting to a source region may also be referred to as a source contact, and a source/drain contact electrically connecting to a drain region may also be referred to as a drain contact.

Still referring to FIG. 4, the SRAM cell 100 further includes a plurality of dielectric features extending lengthwise along the X-direction, including dielectric features 350A, 350B, 350C, and 350D (collectively, dielectric features 350 or referred to as isolation features 350). In the illustrated embodiment, the dielectric feature 350B is disposed between the active region 320A and the active region 320B and abuts the gate structure 330A and the gate structure 330B. The dielectric feature 350B divides an otherwise continuous gate structure into two isolated segments corresponding to the gate structure 330A and the gate structure 330B. The dielectric feature 350C is disposed between the active region 320C and the active region 320D and abuts the gate structure 330C and the gate structure 330D. The dielectric feature 350C divides an otherwise continuous gate structure into two isolated segments corresponding to the gate structure 330C and the gate structure 330D. The dielectric feature 350A is disposed near an edge of the SRAM cell 100 and abuts the gate structure 330C. The dielectric feature 350A divides the gate structure 330C from adjoining other gate structure from an adjacent SRAM cell. The dielectric feature 350D is disposed near another edge of the SRAM cell 100 and abuts the gate structure 330B. The dielectric feature 350D divides gate structure 330B from adjoining other gate structure from an adjacent SRAM cell. Each of the dielectric features 350 is formed by filling a corresponding CMG trench in the position of the dielectric features. The dielectric features 350 are also referred to as CMG features.

In the depicted embodiment, from a top view, the CMG feature 350B is disposed above an interface between the n-well region 314 and the p-well region 316A, the CMG feature 350C is disposed above an interface between the n-well region 314 and the p-well region 316B, the CMG feature 350A is disposed completely above a p-well region that includes the p-well region 316A, and the CMG feature 350D is disposed completely above a p-well region that includes the p-well region 316B.

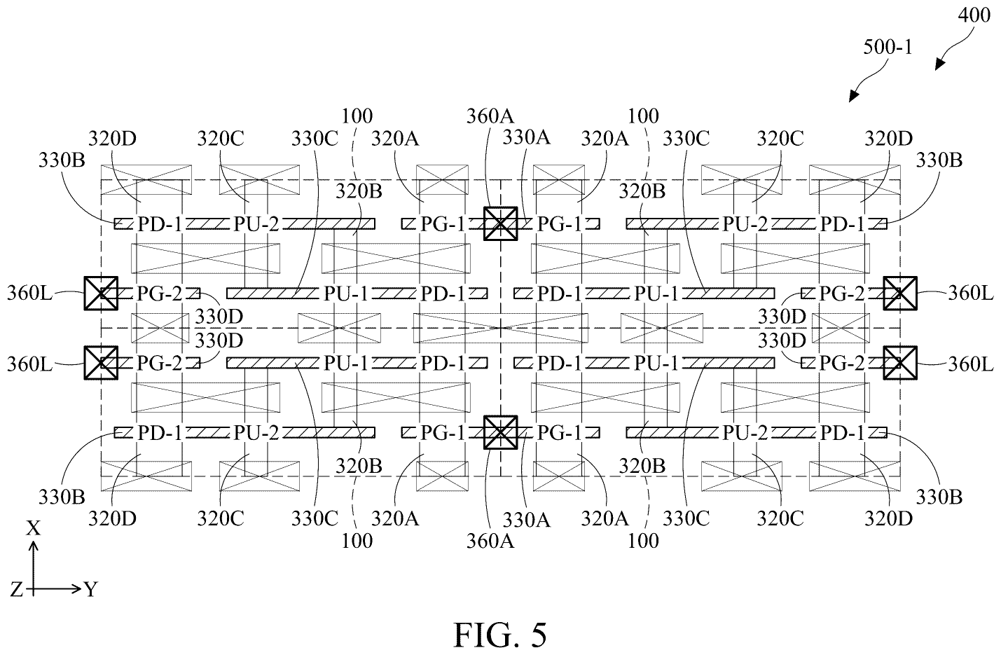

FIG. 5 illustrates a layout 500-1 of a portion of the device layer DL and the frontside multilayer interconnect structure FMLI of an SRAM array 400 according to the present disclosure. Referring to FIG. 5, four SRAM cells are arranged in the X-direction and the Y-direction, forming a 2×2 array of SRAM cells. Each SRAM cell in the array may use the layout of the SRAM cell 100 as depicted in FIG. 4. In the illustrated embodiment, two adjacent SRAM cells in the X-direction are line symmetric with respect to a common boundary therebetween, and two adjacent SRAM cells in the Y-direction are line symmetric with respect to a common boundary therebetween. FIG. 5 has been simplified for visual clarity and to better illustrate the inventive concepts of the present disclosure. For example, some features depicted in FIG. 4, such as well regions, CMG features, and certain gate vias not intended for pass-gate transistors, are omitted in FIG. 5. Additionally, reference numerals from FIG. 4 are repeated in FIG. 5 for case of understanding, but reference numerals for source/drain contacts have also been omitted to aid visual clarity.

For ease of reference, a column is referred to as being in the X-direction of an array, and a row is referred to as being in the Y-direction of an array. As depicted above, adjacent cells in the array are mirror images along a common boundary between the adjacent cells. Some active regions in an SRAM cell may extend through multiple SRAM cells in a column. In FIG. 5, the active region 320A for the transistors PG-1 and PD-1 in one SRAM cell extends into the abutting SRAM cell as the active region for the transistors PD-1 and PG-1 in the abutting SRAM cell. The active region 320B for the transistor PU-1 in one SRAM cell extends into the abutting SRAM cell as the active region for the transistor PU-1 in the abutting SRAM cell. The active region 320D for the transistors PG-2 and PD-2 in one SRAM cell extends into the abutting SRAM cell as the active region for the transistors PD-2 and PG-2 in the abutting SRAM cell. Similarly, some gate structures can be shared by multiple SRAM cells in a row without being interrupted by a CMG feature. For example, the gate structure 330A for the transistor PG-1 in one SRAM cell extends into the abutting SRAM cell as the gate structure for the transistor PG-1 in the abutting SRAM cell. The gate structure 330D for the transistor PG-2 in one SRAM cell extends into the abutting SRAM cell as the gate structure for the transistor PG-2 in the abutting SRAM cell.

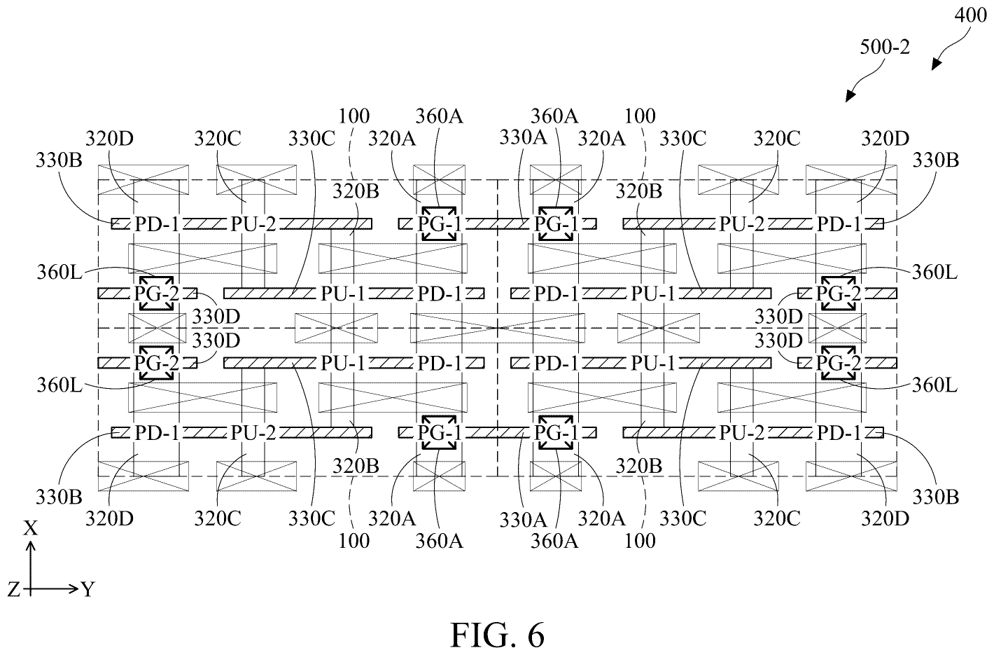

Similarly, the source/drain contacts and gate vias disposed at boundaries of the SRAM cells may also be shared by adjacent SRAM cells. For example, the gate via 360A positioned on the boundary of two SRAM cells in the same row may be shared by two adjacent transistors PG-1 of the adjacent SRAM cells, and the gate via 360L positioned on the boundary of two SRAM cells may be shared by two adjacent transistors PG-2 of the adjacent SRAM cells. Notably, some alternative layouts may have a gate via designated to each respective gate of the corresponding pass-gate transistor. FIG. 6 illustrates such an alternative layout 500-2 of a portion of the device layer DL and the frontside multilayer interconnect structure FMLI of the SRAM array 400. Many aspects of the layout 500-2 are the same as those in the layout 500-1. One difference is that, in the layout 500-2, each of the pass-gate transistors PG-1 has its own gate via 360A landing thereon, and each of the pass-gate transistors PG-2 has its own gate via 360L landing thereon, without sharing with another gate extending from an abutting SRAM cell.

In SRAM device design, the power rails and signal lines are not necessarily all formed on the frontside of the integrated circuit structure but may be distributed on both the frontside and backside of the integrated circuit structure. For example, the integrated circuit structure may include the frontside multilayer interconnect structure FMLI and the backside multilayer interconnect structure BMLI disposed on the frontside and backside of the integrated circuit structure respectively and configured to connect various components of the pull-up transistors, pull-down transistors, and pass-gate transistors to form the SRAM cells. The configuration is designed with considerations of various factors and parameters, including sizes of various conductive features, packing density, resistance of the conductive features, parasitic capacitances among adjacent conductive features, overlay shifting and processing margins. In the following illustrated embodiments, while a portion of the power rails and the signal lines is formed on the frontside of the SRAM device, another portion of the power rails and the signal lines is also formed on the backside of the SRAM device. For example, the gate vias for the pass-gate transistors may also be formed on the backside of the SRAM cells as backside gate vias.

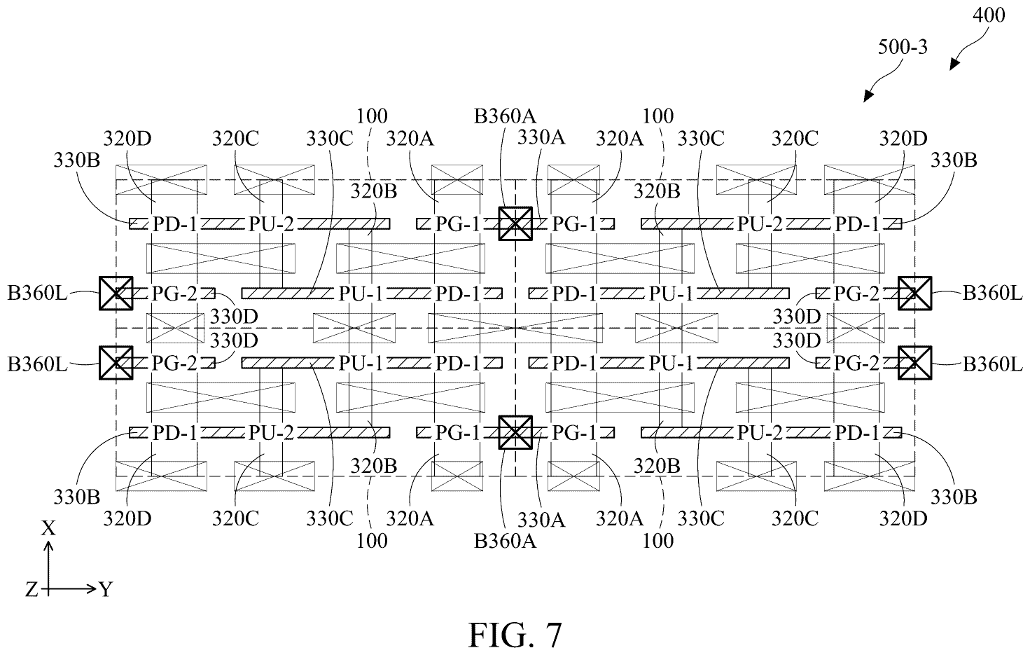

Reference is now made to FIG. 7. FIG. 7 illustrates a layout 500-3 of a portion of the backside multilayer interconnect structure BMLI of the SRAM array 400, which includes a backside via zero level (BV0 level). For reasons of visual clarity and to better understand the inventive concepts of the present disclosure, in the BV0 level only the backside gate vias landing on the backside of the gate structures of the pass-gate transistors PG-1 and PG-2 are shown. Meanwhile, active regions, gate structures, and source/drain contacts as depicted in FIG. 5 or FIG. 6, which are at the frontside of the SRAM array 400, are overlaying on the layout 500-3 to aid visual clarity. Yet, gate vias 360A and 360L as depicted in FIG. 5 or FIG. 6, which are a part of the frontside multilayer interconnect structure FMLI, are omitted in FIG. 7.

The backside gate via B360A is formed directly under and in direct contact with the gate structure of the pass-gate transistor PG-1, and the backside gate via B360L is formed directly under and in direct contact with the gate structure of the pass-gate transistor PG-2. Particularly, as depicted in FIG. 7, the backside gate via B360A positioned on the boundary of two SRAM cells in the same row is shared by two adjacent pass-gate transistors PG-1 of the adjacent SRAM cells, and the backside gate via B360L positioned on the boundary of two SRAM cells in the same row is shared by two adjacent pass-gate transistors PG-2 of the adjacent SRAM cells.

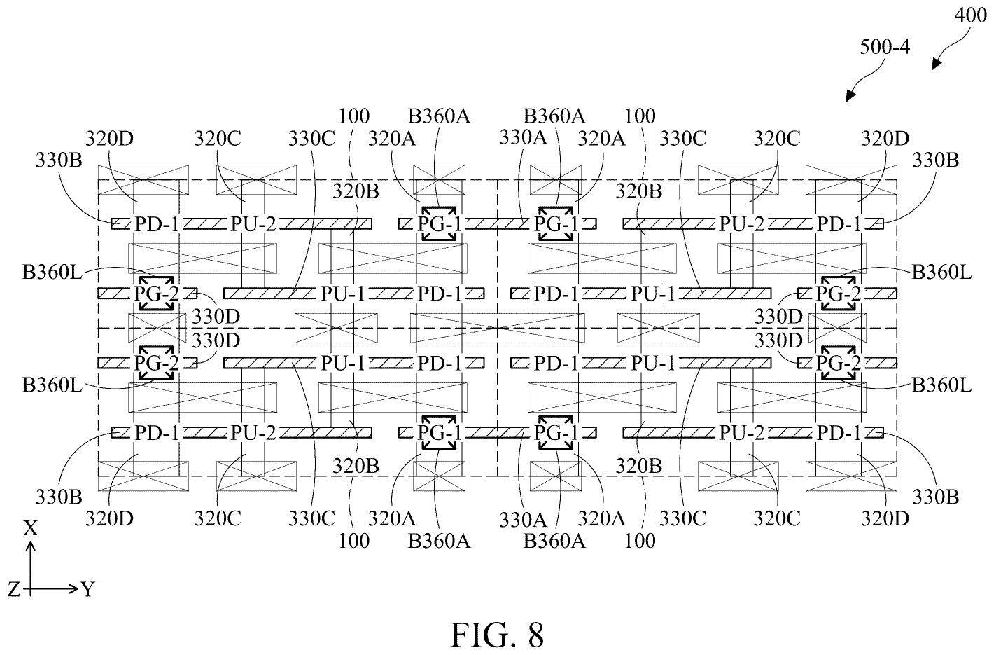

Similarly, as discussed above with reference to FIG. 6, some alternative layouts may have a backside gate via designated to each respective gate of the corresponding pass-gate transistor. FIG. 8 illustrates such an alternative layout 500-4 of a portion of the device layer DL and the backside multilayer interconnect structure BMLI of the SRAM array 400. Many aspects of the layout 500-4 are the same as those in the layout 500-3. One difference is that, in the layout 500-4, each of the pass-gate transistors PG-1 has its own backside gate via B360A landing thereunder, and each of the pass-gate transistors PG-2 has its own backside gate via B360L landing thereunder, without sharing with another gate extending from an abutting SRAM cell.

Notably, depending on design considerations, either of the frontside multilayer interconnect structures FMLI depicted in the layouts 500-1 and 500-2 may be adopted in an SRAM device. Similarly, either of the backside multilayer interconnect structures BMLI depicted in the layouts 500-3 and 500-4 may be independently adopted in the SRAM device. In other words, considering a region containing the gate structure 330A shared by two adjacent pass-gate transistors PG-1 as an example, there can be eight different configurations to implement based on design considerations: a first configuration may include one shared frontside gate via 360A and one shared backside gate via B360A; a second configuration may include one shared frontside gate via 360A and two individual backside gate vias B360A; a third configuration may include two individual frontside gate vias 360A and one shared backside gate via B360A; a fourth configuration may include two individual frontside gate vias 360A and two individual backside gate vias B360A; a fifth configuration may include one shared frontside gate via 360A with no backside gate via; a sixth configuration may include two individual frontside gate vias 360A with no backside gate via; a seventh configuration may include one shared backside gate via B360A with no frontside gate via; and an eighth configuration may include two shared backside gate vias B360A with no frontside gate via.

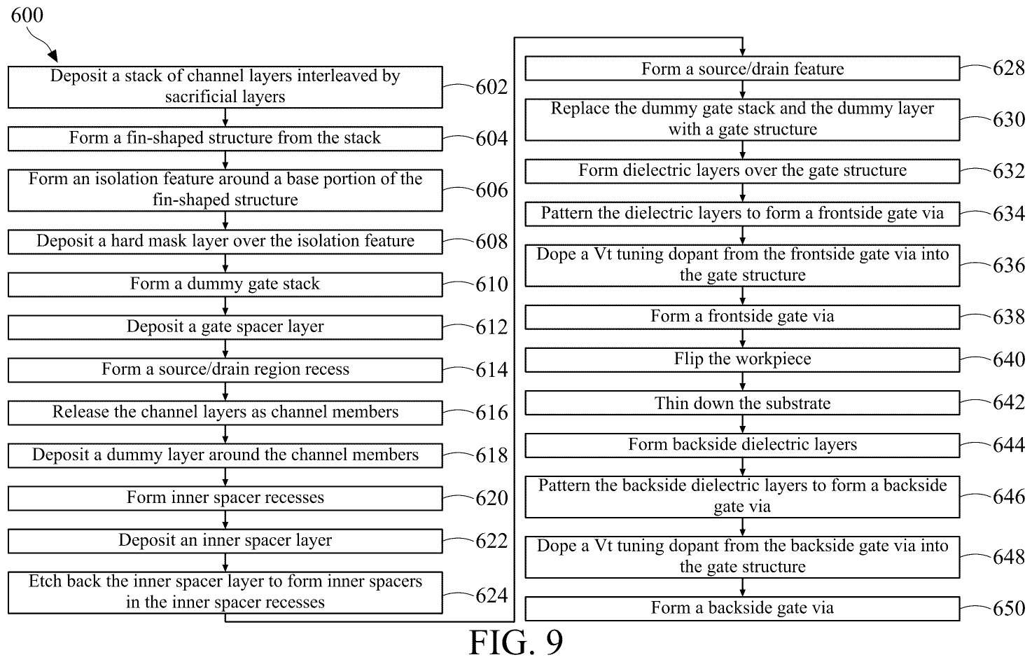

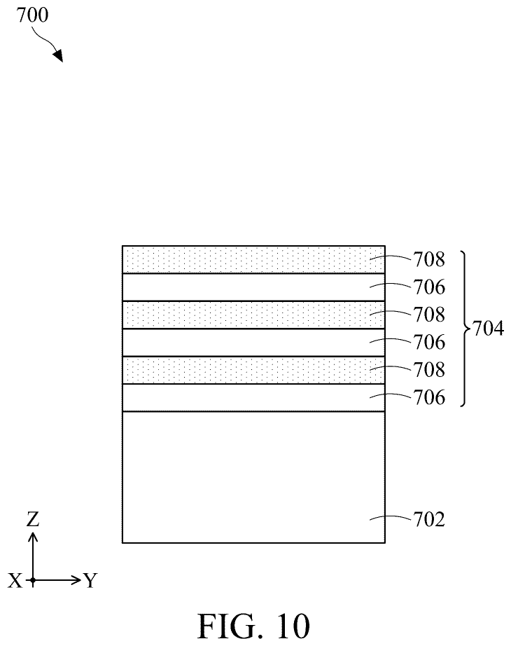

Since the pass-gate transistors have associated frontside and/or backside gate vias for electrical connections to word lines, while the pull-down transistors do not, the formation of these gate vias for the pass-gate transistors provides an opportunity to separately increase the threshold voltage of the pass-gate transistors, thereby achieving a beta ratio greater than 1. The manufacturing flow will now be described in detail with reference to the following figures. In that regard, FIG. 9 is a flowchart illustrating a method 600 of forming a semiconductor device from a work-in-progress (WIP) structure according to embodiments of the present disclosure. Method 600 is merely an example and is not intended to limit the present disclosure to what is explicitly illustrated in method 600. Additional steps can be provided before, during, and after method 600, and some steps described can be replaced, eliminated, or moved around for additional embodiments of the method. Not all steps are described herein in detail for reasons of simplicity. Method 600 is described below in conjunction with FIGS. 10-44, which are fragmentary cross-sectional views of a WIP structure 700 at different stages of fabrication according to embodiments of method 600 in FIG. 9. Because the WIP structure 700 will be fabricated into a semiconductor device or a semiconductor structure, the WIP structure 700 may be referred to herein as a semiconductor device 700 or a semiconductor structure 700 as the context requires.

Referring to FIGS. 9 and 10, method 600 includes a block 602 where a stack 704 of alternating semiconductor layers is formed over the WIP structure 700. As shown in FIG. 10, the WIP structure 700 includes a substrate 702. In some embodiments, the substrate 702 may be a semiconductor substrate such as a silicon (Si) substrate. The substrate 702 may include various doping configurations depending on design requirements as is known in the art. In embodiments where the semiconductor device is p-type, an n-type doping profile (i.e., an n-type well or n-well) may be formed on the substrate 702. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 702. In some implementations, the p-type dopant for forming the p-type well may include boron (B) or gallium (Ga). The suitable doping may include ion implantation of dopants and/or diffusion processes. The substrate 702 may also include other semiconductors such as germanium (Ge), silicon carbide (SiC), silicon germanium (SiGe), germanium tin (GeSn), or diamond. Alternatively, the substrate 702 may include a compound semiconductor and/or an alloy semiconductor. Further, the substrate 702 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 704 over the substrate 702 includes channel layers 708 of a first semiconductor composition interleaved by sacrificial layers 706 of a second semiconductor composition. It can also be said that the sacrificial layers 706 are interleaved by the channel layers 708. The first and second semiconductor composition may be different. In some embodiments, the sacrificial layers 706 include silicon germanium (SiGe) or germanium tin (GeSn) and the channel layers 708 include silicon (Si). It is noted that three (3) layers of the sacrificial layers 706 and three (3) layers of the channel layers 708 are alternately arranged as illustrated in FIG. 10, which is for illustrative purposes only and not intended to be limiting beyond what is specifically recited in the claims. It can be appreciated that any number of epitaxial layers may be formed in the stack 704. The number of layers depends on the desired number of channels members for the semiconductor device 700. In some embodiments, the number of channel layers 708 is between 2 and 10.

The sacrificial layers 706 and channel layers 708 in the stack 704 may be deposited using a molecular beam epitaxy (MBE) process, a vapor phase deposition (VPE) process, and/or other suitable epitaxial growth processes. As stated above, in at least some examples, the sacrificial layers 706 include an epitaxially grown silicon germanium (SiGe) layer and the channel layers 708 include an epitaxially grown silicon (Si) layer. In some embodiments, the sacrificial layers 706 and the channel layers 708 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 704.

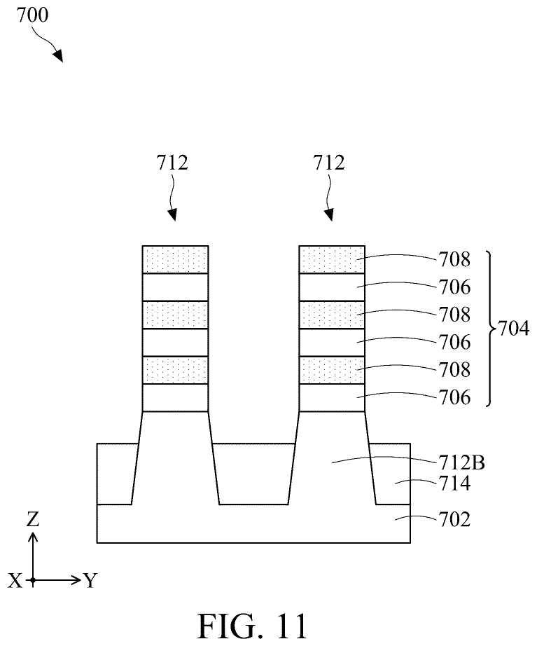

Referring to FIGS. 9 and 11, method 600 includes a block 604 where fin-shaped structures 712 are formed from the stack 704 and the substrate 702. In some implementations, the two fin-shaped structures 712 as depicted in FIG. 11 represent the two active regions 320A (or 320D) in FIGS. 5-8. To pattern the stack 704, a hard mask layer may be deposited over the stack 704 to form an etch mask. The hard mask layer may be a single layer or a multi-layer. For example, the hard mask layer may include a pad oxide layer and a pad nitride layer disposed over the pad oxide layer. The fin-shaped structure 712 may be patterned from the stack 704 and the substrate 702 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 11, the etch process at block 604 forms trenches extending vertically through the stack 704 and a portion of the substrate 702. The trenches define the fin-shaped structures 712. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 712 by etching the stack 704 and a portion of the substrate 702. As shown in FIG. 11, the fin-shaped structure 712 that includes the sacrificial layers 706 and the channel layers 708 extends vertically along the Z direction and lengthwise along the X direction. Each of the fin-shaped structures 712 includes a base fin structure 712B patterned from the substrate 702 and the patterned stack 704 disposed directly over the base fin structure 712B.

Referring to FIGS. 9 and 11, method 600 includes a block 606 where an isolation feature 714 is formed around a base fin structure 712B of the fin-shaped structures 712. In some embodiments represented in FIG. 11, the isolation feature 714 is disposed on sidewalls of the base fin structure 712B. In some embodiments, the isolation feature 714 may be formed in the trenches to isolate the fin-shaped structures 712 from a neighboring fin-shaped structure. The isolation feature 714 may also be referred to as a shallow trench isolation (STI) feature 714. By way of example, in some embodiments, a dielectric layer is first deposited over the substrate 702, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 714 shown in FIG. 11. The fin-shaped structure 712 rises above the STI feature 714 after the recessing, while the base fin structure 712B is embedded or buried in the STI feature 714.

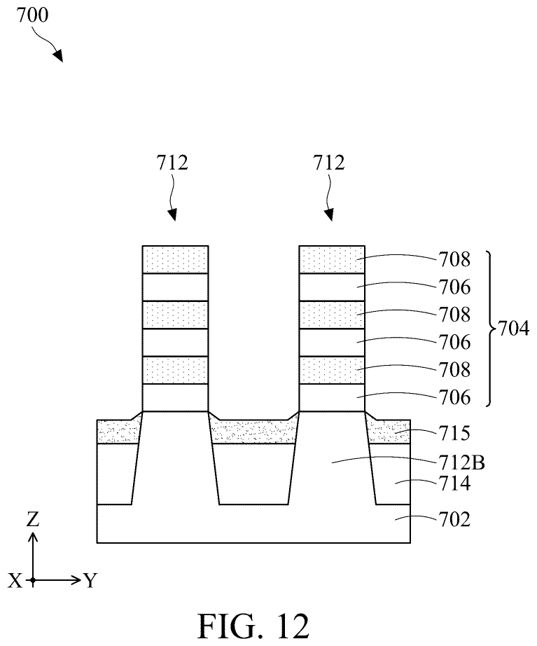

Referring to FIGS. 9 and 12, method 600 includes a block 608 where a hard mask layer 715 is formed over the STI feature 714 and around a top portion of the base fin structure 712B. A composition of the hard mask layer 715 is different from a composition of the STI feature 714 to ensure that each one of them may be selectively etched without substantially damaging the other one. In some embodiments, the STI feature 714 includes an oxide, and the hard mask layer 715 includes a nitride (e.g., silicon nitride) or an oxynitride (e.g., silicon oxynitride). By way of example, in some embodiments, a nitride-containing material is first deposited over the STI feature 714, filling the trenches with nitride. In various examples, the nitride-containing material may be deposited by a CVD process, a subatmospheric CVD (SACVD) process, a flowable CVD process, a spin-on coating process, and/or other suitable process. The deposited nitride-containing material is then thinned and planarized, for example by a chemical mechanical polishing (CMP) process. The planarized nitride-containing material is further recessed or pulled-back by a dry etching process, a wet etching process, and/or a combination thereof to form the hard mask layer 715. The fin-shaped structure 712 rises above the hard mask layer 715 after the recessing, while the base fin structure 712B is embedded or buried in the combination of the STI feature 714 and the hard mask layer 715.

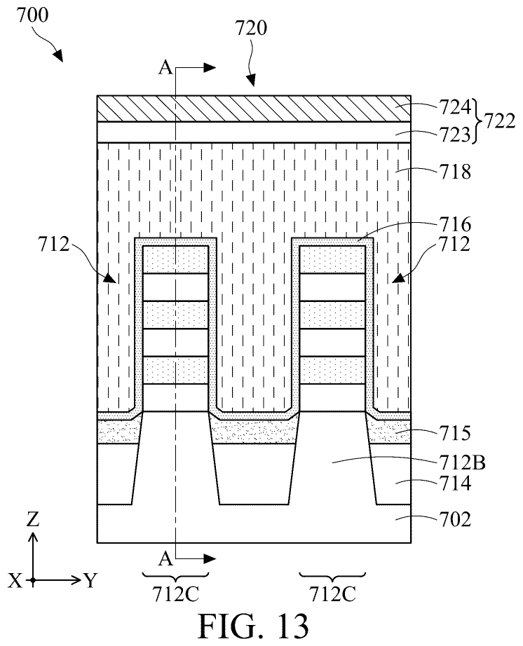

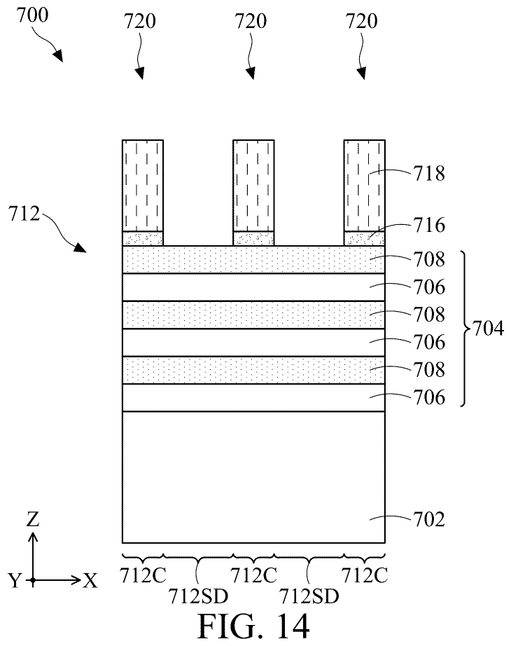

Referring to FIGS. 9 and 13-14, method 600 includes a block 610 where a dummy gate stack 720 is formed over a channel region 712C of the fin-shaped structure 712. The dummy gate stack 720 serves as a placeholder to undergo various processes and is to be removed and replaced by a functional gate structure. In some implementations, the to-be-formed functional gate structure represents the gate structure 330A (or gate structure 330D) in FIGS. 5-8. In some embodiments illustrated in FIG. 14, which is a cross-sectional view cut along the A-A line in FIG. 13, the dummy gate stack 720 is formed over the fin-shaped structure 712 and the fin-shaped structure 712 may be divided into channel regions 712C underlying the dummy gate stacks 720 and source/drain regions 712SD that do not underlie the dummy gate stacks 720. The channel regions 712C are adjacent to the source/drain regions 712SD. As shown in FIG. 14, the channel region 712C is disposed between two source/drain regions 712SD along the X direction.

The formation of the dummy gate stack 720 may include deposition of layers in the dummy gate stack 720 and patterning of these layers. Referring to FIG. 13, a dummy dielectric layer 716, a dummy electrode layer 718, and a gate-top hard mask layer 722 may be blanketly deposited over the WIP structure 700. The dummy dielectric layer 716 may be formed on the fin-shaped structure 712 using a chemical vapor deposition (CVD) process, an ALD process, an oxygen plasma oxidation process, or other suitable processes. In some instances, the dummy dielectric layer 716 may include silicon oxide. Thereafter, the dummy electrode layer 718 may be deposited over the dummy dielectric layer 716 using a CVD process, an ALD process, or other suitable processes. In some instances, the dummy electrode layer 718 may include polysilicon. For patterning purposes, the gate-top hard mask layer 722 may be deposited on the dummy electrode layer 718 using a CVD process, an ALD process, or other suitable processes. The gate-top hard mask layer 722, the dummy electrode layer 718, and the dummy dielectric layer 716 may then be patterned to form the dummy gate stack 720, as shown in FIG. 13. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 722, the dummy electrode layer 718, and the dummy dielectric layer 716. In some embodiments, the etching process may include dry etching (e.g., RIE etching), wet etching, and/or other etching methods. In some embodiments, the gate-top hard mask layer 722 may include a silicon oxide layer 723 and a silicon nitride layer 724 over the silicon oxide layer 723. As shown in FIG. 14, the dummy gate stack 720 is patterned such that it is only disposed over the channel region 712C, not disposed over the source/drain region 712SD.

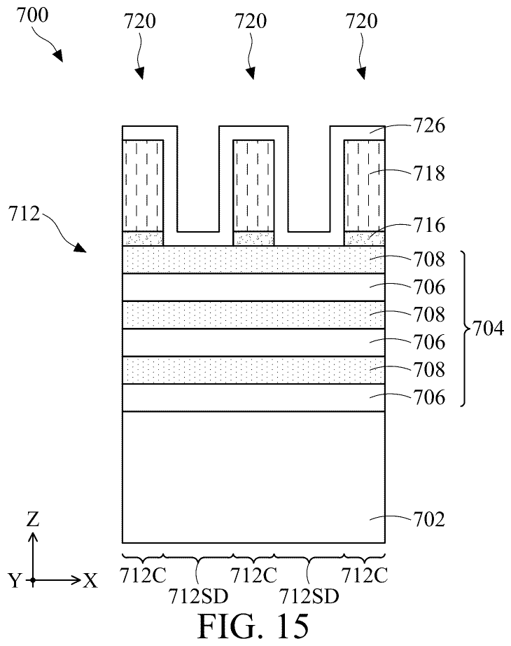

Referring to FIGS. 9 and 15, method 600 includes a block 612 where a gate spacer layer 726 is deposited over the WIP structure 700, including over the dummy gate stack 720. In some embodiments, the gate spacer layer 726 is deposited conformally over the WIP structure 700, including over top surfaces and sidewalls of the dummy gate stack 720. The term “conformally” may be used herein for ease of description of a layer having substantially uniform thickness over various regions. The gate spacer layer 726 may be a single layer or a multi-layer. The at least one layer in the gate spacer layer 726 may include silicon carbonitride, silicon oxycarbide, silicon oxycarbonitride, or silicon nitride. The gate spacer layer 726 may be deposited over the dummy gate stack 720 using processes such as, a CVD process, a subatmospheric CVD (SACVD) process, an ALD process, or other suitable process.

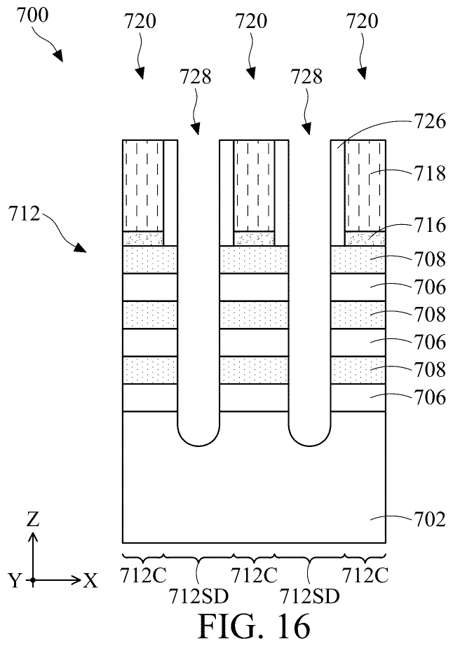

Referring to FIGS. 9 and 16, method 600 includes a block 614 where source/drain regions 712SD of the fin-shaped structure 712 are anisotropically recessed to form source/drain trenches 728. The anisotropic etch may include a dry etch or a suitable etch process that etches the source/drain regions 712SD and a portion of the substrate 702. The resulting source/drain trench 728 extends vertically through the depth of the stack 704 and partially into the substrate 702. An example dry etch process for block 614 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 16, the source/drain regions 712SD of the fin-shaped structure 712 are recessed to expose sidewalls of the sacrificial layers 706 and the channel layers 708. Because the source/drain trenches 728 extend below the stack 704 into the substrate 702, the source/drain trenches 728 include bottom surfaces and lower sidewalls defined in the substrate 702.

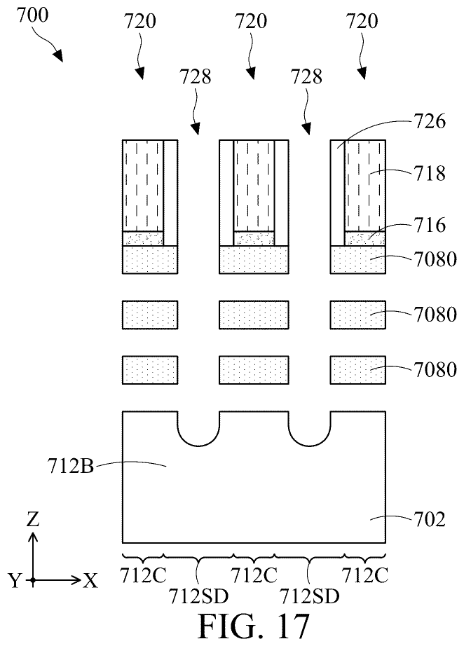

Referring to FIGS. 9 and 17, method 600 includes a block 616 where the plurality of channel layers 708 in the channel regions are released as channel members 7080. Depending on the design, the channel members 7080 may take form of nanowires, nanosheets, or other nanostructures. After the formation of the source/drain trench 728, the sacrificial layers 706 interleaving the channel layers 708 in the channel region 712C are selectively removed. The selective removal of the sacrificial layers 706 releases the channel layers 708 to form channel members 7080 shown in FIG. 17. The selective removal of the sacrificial layers 706 forms spaces between and around adjacent channel members 7080. The selective removal of the sacrificial layers 706 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

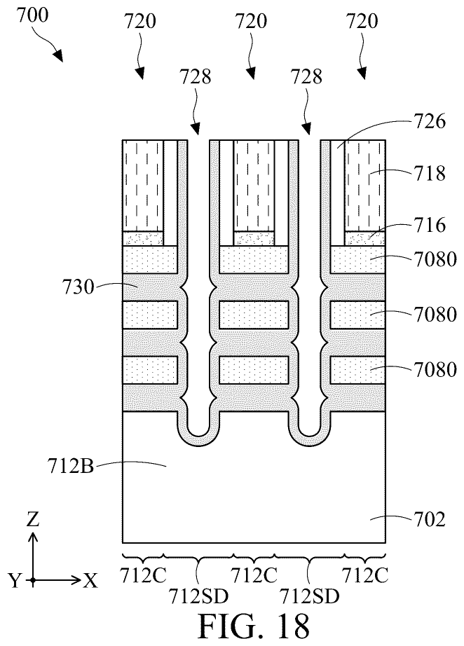

Referring to FIGS. 9 and 18, method 600 includes a block 618 where a dielectric dummy layer 730 is deposited around the channel members 7080 and over the source/drain trenches 728. The dummy layer 730 may include silicon oxide and may be deposited using plasma enhanced chemical vapor deposition (PECVD) or ALD. The dummy layer 730 fills the space among the channel members 7080 and covers end sidewalls of the channel members 7080. Additionally, the dummy layer 730 is in direct contact with a sidewall of the gate spacer layer 726 and a top surface of the substrate 702.

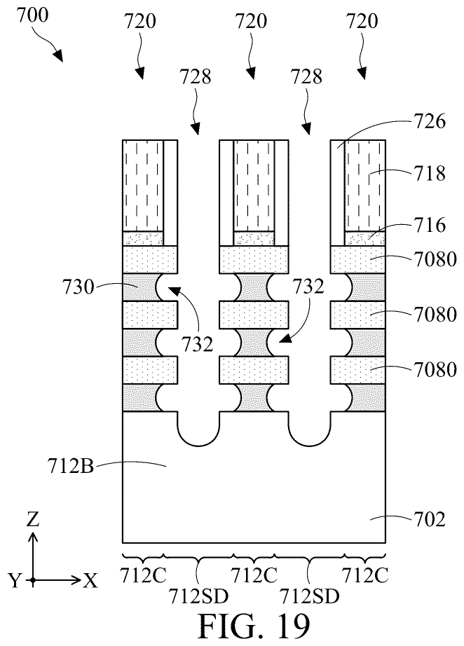

Referring to FIGS. 9 and 19, method 600 includes a block 620 where inner spacer recesses 732 are formed. The dummy layers 730 are selectively and partially recessed to form inner spacer recesses 732 while the gate spacer layer 726, the dummy gate stack 720, the exposed portion of the substrate 702, and the channel layers 708 are substantially unetched. In an embodiment where the channel layers 708 consist essentially of silicon (Si) and the dummy layers 730 are formed of silicon oxide, the selective recess of the dummy layer 730 may be performed using a selective wet etch process or a selective dry etch process. An example selective dry etching process may include use of carbon tetrafluoride (CF₄), nitrogen trifluoride (NF₃), hydrogen (H₂), or a mixture thereof. An example selective wet etching process may include use of hydrofluoric acid, ammonium fluoride, or a mixture thereof.

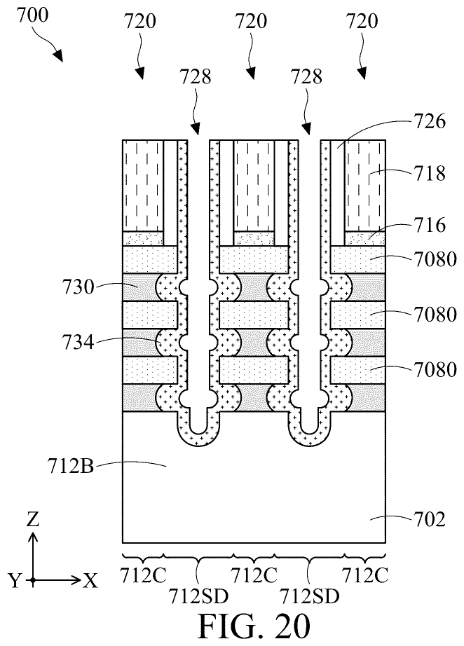

Referring to FIGS. 9 and 20, method 600 includes a block 622 where an inner spacer layer 734 is deposited over the inner spacer recesses 732. A composition of the inner spacer layer 734 is different from a composition of the dielectric dummy layer 730 to ensure that each one of them may be selectively etched without substantially damaging the other one. In some embodiments, the inner spacer layer 234 may include silicon carbonitride (SiCN), silicon oxycarbonitride (SiOCN), silicon nitride (SIN), silicon oxycarbide (SiOC), or silicon oxynitride (SiON). In some implementations, the inner spacer layer 734 may be deposited using CVD or ALD.

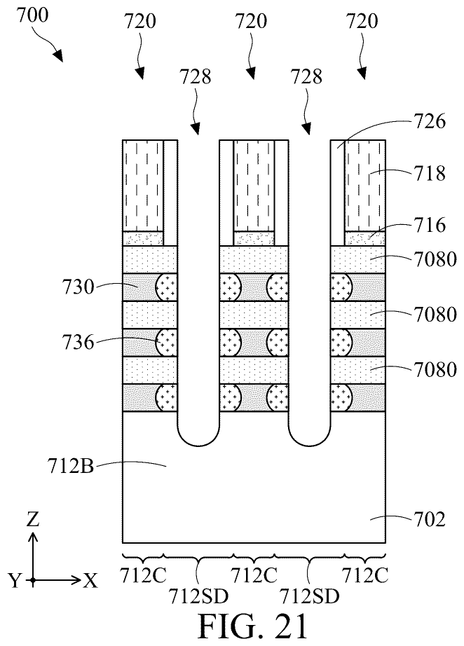

Referring to FIGS. 9 and 21, method 600 includes a block 624 where the inner spacer layer 734 is etched back to form inner spacers 736 over the inner spacer recesses 732. In some embodiments, the etching back at block 624 may include use of a dry etching process, such as a reactive ion etching (RIE) process that is aided by plasma. An example dry etching process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof. In the depicted embodiment, the inner spacers 736 laterally extend to a position directly under the dummy gate stack 720. Alternatively, the inner spacers 736 may substantially remain under the gate spacer layer 726 without extending to a position directly under the dummy gate stack 720.

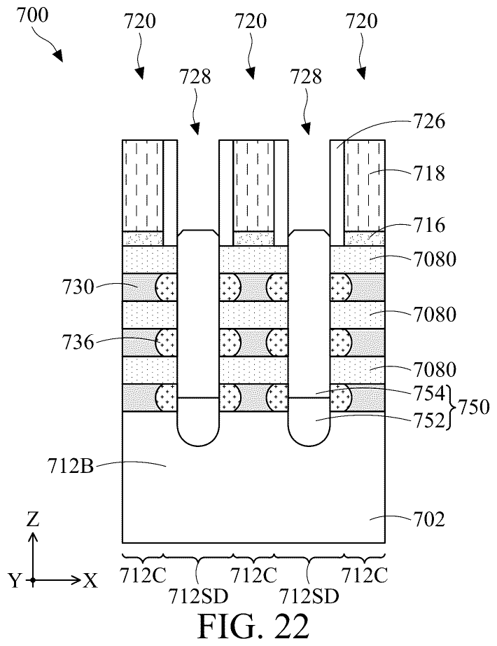

Referring to FIGS. 9 and 22, method 600 includes a block 628 where a source/drain feature 750 is formed over the source/drain region 212SD. While not explicitly shown, before any of the epitaxial layers are formed, method 600 may include a cleaning process to clean surfaces of the WIP structure 700. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

In some embodiments, a source/drain feature 750 includes a bottom epitaxial feature 752 and a main epitaxial feature 754 over the bottom epitaxial feature 752. The source/drain feature 750 may be n-type or p-type. Particularly, when the source/drain feature 750 is a part of the pass-gate transistors PG-1 and PG-2 as depicted in FIGS. 5-8, the source/drain feature 750 may be n-type. When the source/drain feature 750 is n-type, the bottom epitaxial feature 752 may include undoped silicon (Si) or undoped silicon germanium (SiGe) and the main epitaxial feature 754 may include silicon (Si) and an n-type dopant, such as phosphorus (P), arsenic (As), antimony (Sb), or a combination thereof. When the source/drain feature 750 is p-type, the bottom epitaxial feature 752 may include undoped silicon (Si) or undoped silicon germanium (SiGe) and the main epitaxial feature 754 may include silicon germanium (SiGe) and a p-type dopant, such as boron (B), boron difluoride (BF₂), or a combination thereof. As used herein, the undoped semiconductor material is regarded as undoped when it is not intentionally doped. In some alternative embodiments, the bottom epitaxial feature 752 may include a counter dopant to reduce leakage into the bulk substrate 702. For example, the bottom epitaxial feature 752 in the n-type source/drain feature 750 may include a p-type dopant, such as boron (B). For another example, the bottom epitaxial feature 752 in the p-type source/drain feature 750 may include an n-type dopant, such as phosphorus (P), arsenic (As), or antimony (Sb). The source/drain feature 750 may be formed using vapor-phase epitaxy (VPE), ultra-high vacuum CVD (UHV-CVD), or molecular beam epitaxy (MBE). Doping of the source/drain features 750 may be achieved with in-situ doping.

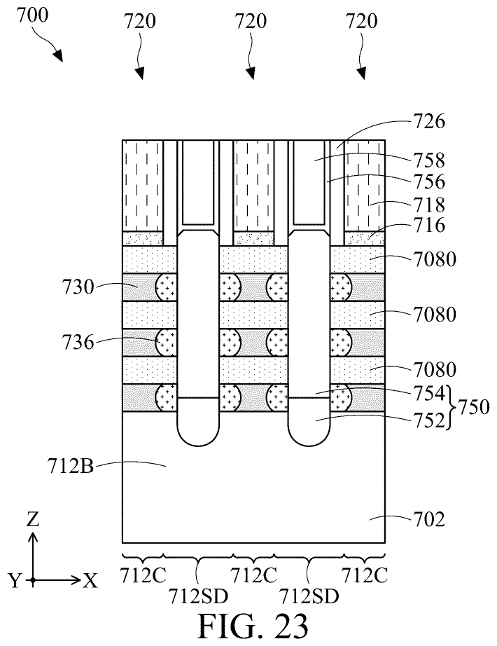

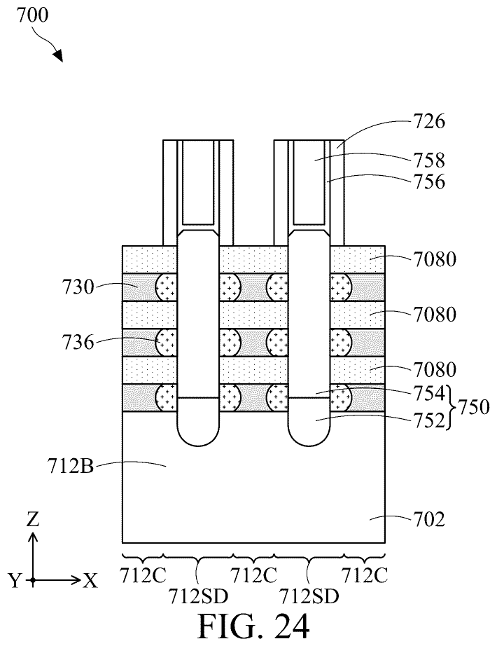

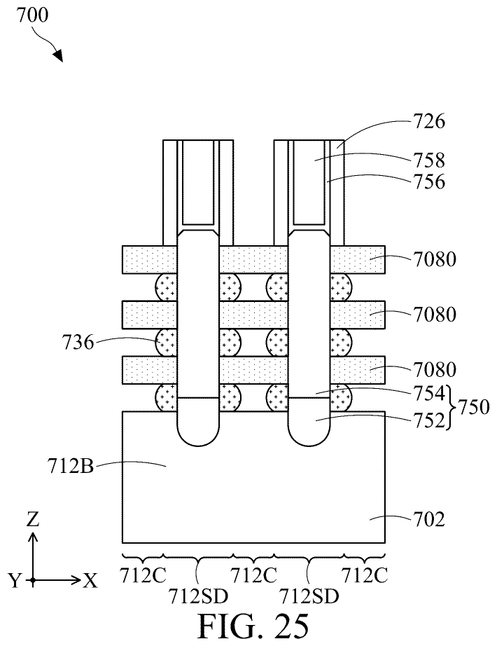

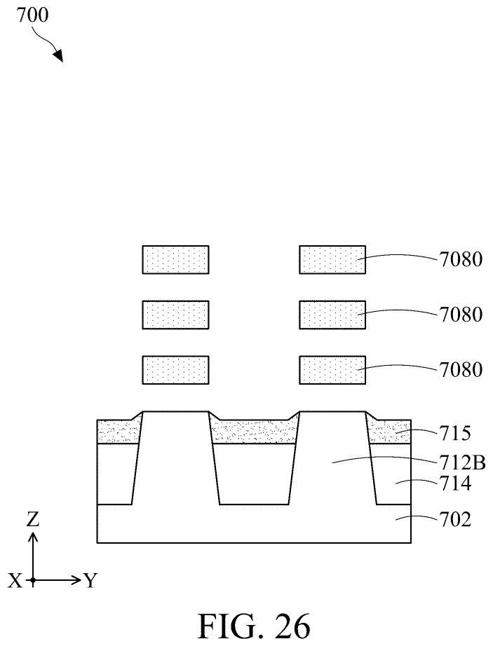

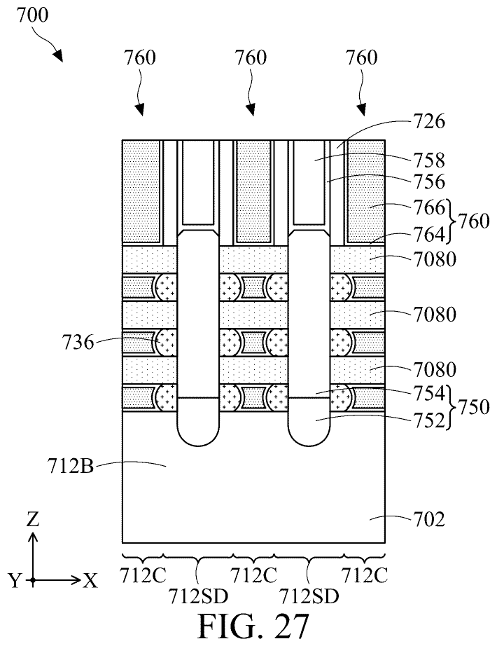

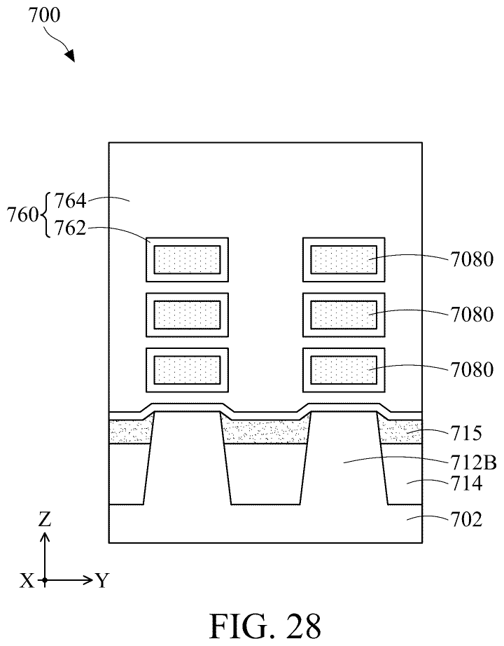

Referring to FIGS. 1 and 23-28, method 600 includes a block 630 where the dummy gate stack 720 and the dummy layer 730 are replaced with a gate structure 760 (also referred to as metal gate structure 760). Operations at block 630 may include deposition of a contact etch stop layer (CESL) 756 over the source/drain features 750 (shown in FIG. 23), deposition of an interlayer dielectric layer 758 over the CESL 756 (shown in FIG. 23), removal of the dummy gate stack 720 (shown in FIG. 24), removal of the dummy layer 730 (shown in FIGS. 25 and 26), and deposition of the gate structure 760 to wrap around each of the channel members 7080 (shown in FIGS. 27 and 28). Referring to FIG. 23, the CESL 756 is deposited over the WIP structure 700, including over the source/drain feature 750. The CESL 756 may include silicon nitride or aluminum nitride. In some implementations, the CESL 756 may be deposited using CVD or atomic layer deposition (ALD). The ILD layer 758 is then deposited over the CESL 756. In some embodiments, the ILD layer 758 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 758 may be deposited using CVD, flowable CVD (FCVD), spin-on coating, or a suitable deposition technique. After the deposition of the ILD layer 758, the WIP structure 700 may be planarized by a planarization process to expose the dummy gate stack 720. For example, the planarization process may include a chemical mechanical planarization (CMP) process. Exposure of the dummy gate stack 720 allows the removal of the dummy gate stack 720. The removal of the dummy gate stack 720 may include one or more etching processes that are selective to the material of the dummy gate stack 720. For example, the removal of the dummy gate stack 720 may be performed using as a selective wet etch, a selective dry etch, or a combination thereof that is selective to the dummy gate stack 720.

After the removal of the dummy gate stack 720, the dummy layer 730 in the channel region 712C is exposed. A separate etch process may be performed to selectively remove the dummy layer 730 in the channel region 712C. For example, a selective wet etch process or a selective dry etch process may be performed to remove the dummy layer 730. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. The selective etch of the dummy layer 730 etches the channel members 7080 at a much smaller rate, such that the integrity of the channel members 7080 is preserved. The hard mask layer 715 also protects the STI feature 714 from the etching loss during the removal of the dummy layer 730. After the selective removal of the dummy layer 730, the channel members 7080 in the channel region 712C are once again exposed as shown in FIGS. 25 and 26.

After the release of the channel members 7080, the gate structure 760 is formed to wrap around each of the channel members 7080 as shown in FIGS. 27 and 28. The gate structure 760 includes a gate dielectric layer 762 interfacing the channel members 7080 and the substrate 702 in the channel region 712C and a gate electrode layer 764 over the gate dielectric layer 762.

The gate dielectric layer 762 may include an interfacial layer and a high-k dielectric layer over the interfacial layer The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-k dielectric layer may include a high-k dielectric material, such as hafnium oxide. Alternatively, the high-k dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The high-k dielectric layer may be formed by ALD, physical vapor deposition (PVD), CVD, oxidation, and/or other suitable methods. The gate dielectric layer 762 also covers sidewalls of the inner spacers 736.

The gate electrode layer 764 of the gate structure 760 may include a multi-layer structure, such as various combinations of a metal layer with a selected work function to enhance the device performance (referred to as work function metal (WFM) layer), a liner layer, a wetting layer, an adhesion layer, a metal alloy or a metal silicide. By way of example, the gate electrode layer 766 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 764 may be formed by ALD, PVD, CVD, e-beam evaporation, or other suitable process. In various embodiments, a CMP process may be performed to remove excessive metal, thereby providing a substantially planar top surface of the gate structure 760. The gate structure 760 includes portions that interpose between channel members 7080 in the channel region 712C. In some embodiments, the gate structure 760 may be an n-type gate structure or a p-type gate structure. The n-type gate structure includes an n-type work function metal layer disposed closer to the channel members 7080. The p-type gate structure includes a p-type work function metal layer disposed closer to the channel members 7080. In some implementations, the gate structure 760 is an n-type gate structure, representing the gate structure 330A (or gate structure 330D) in FIGS. 5-8 and including an n-type WFM layer wrapping around each of the channel members 7080.

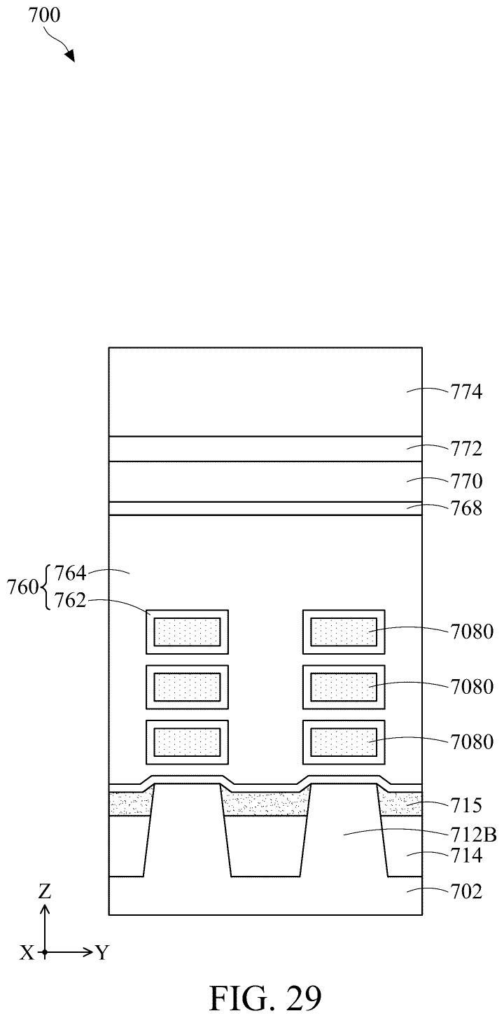

Referring to FIGS. 9 and 29, method 600 includes a block 632 where one or more dielectric layers as part of a frontside multilayer interconnect structure FMLI are formed over the gate structure 760. In the illustrated embodiment, an etch stop layer (ESL) 768 is deposited over the gate structure 760, an interlayer dielectric layer (ILD) 770 is deposited over the ESL 768, an ESL 772 is deposited over the ILD 770, and an ILD 774 is deposited over the ESL 772. Each of the ESLs 768 and 772 may comprise silicon carbide, silicon oxynitride, silicon carbo-nitride, or the like, and formed by CVD, PVD, ALD, or other suitable deposition processes; each of the ILDs 770 and 774 may comprise a material selected from PSG, BSG, PBSG, FSG, TEOS, or other non-porous porous low-k dielectric materials, and formed by flowable CVD, PE-CVD, LP-CVD, spin-on coating, or other suitable deposition processes.

Referring to FIGS. 9 and 30-31, method 600 includes a block 634 where a tri-layer resist layer 776 is formed over the ILD 774 and patterned to form a gate via opening 784. The tri-layer resist layer 776 includes a bottom layer 778, a middle layer 780, and an upper layer 782. The bottom layer 778 may be a bottom anti-reflective coating (BARC). The bottom layer 778 may include organic materials. The middle layer 780 may be formed from or include an inorganic material, which may be a nitride (such as silicon nitride), an oxynitride (such as silicon oxynitride), an oxide (such as silicon oxide), or the like. The upper layer 782 is a photosensitive material. The middle layer 780 has a high etching selectivity relative to the upper layer 782 and the bottom layer 778. As a result, the upper layer 782 is used as an etching mask for the patterning of the middle layer 780, and the middle layer 780 is used as an etching mask for the patterning of the bottom layer 778. In some embodiments, the resist layer formed over the ILD 774 may be another type of photoresist, such as a single-layer photoresist, a bi-layer photoresist, or the like.

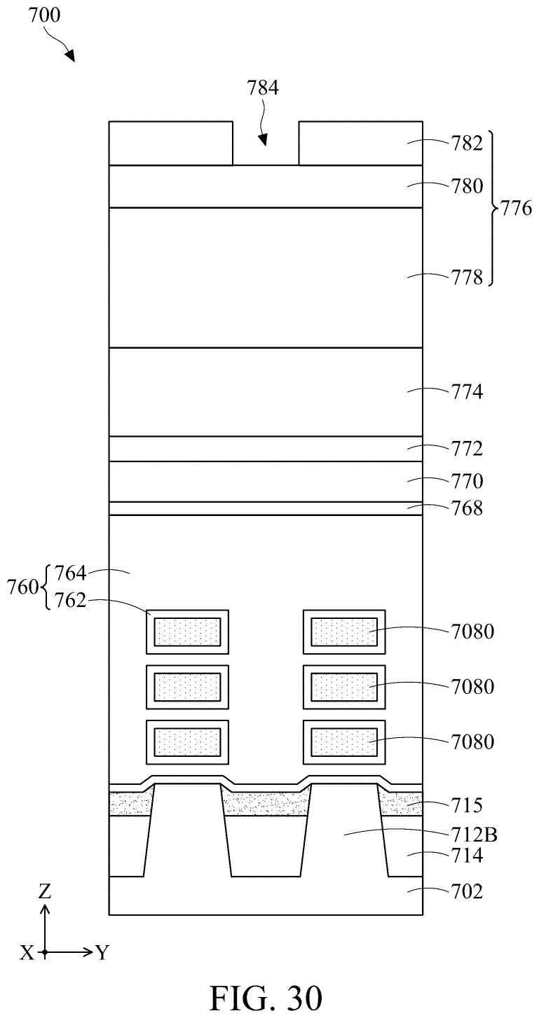

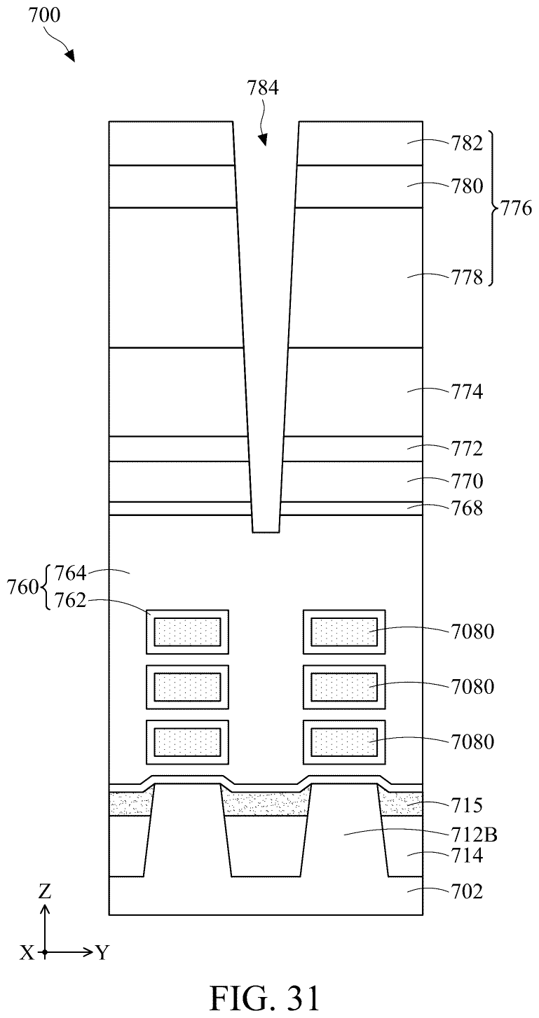

At block 634, the upper layer 782 is patterned using any suitable photolithography technique to form an opening therein, as shown in FIG. 30. As an example of patterning the upper layer 782, the upper layer 782 may be exposed to a radiation beam including an UV or an excimer laser such as a 248 nm beam from a Krypton Fluoride (KrF) excimer laser, a 193 nm beam from an Argon Fluoride (ArF) excimer laser, or a 157 nm beam from a F₂ excimer laser. Exposure of the photosensitive material may be performed using an immersion lithography system to increase resolution and decrease the minimum achievable pitch. A bake or cure operation may be performed to harden the upper layer 782, and a developer may be used to remove either the exposed or unexposed portions of the upper layer 782 depending on whether a positive or negative resist is used. Subsequently, the opening defined in the upper layer 782 is transferred to the underneath layers using one or more suitable etching processes, as shown in FIG. 31. The extended opening is referred to as the gate via opening 784. The gate via opening 784 is extended to the gate electrode layer 764 by etching through the middle layer 780, bottom layer 778, ILD 774, ESL 772, ILD 770, and ESL 768 using one or more suitable etching processes. The etching processes may over-etch into the gate electrode layer 764, such that the gate via opening 784 extends to a position below a top surface of the gate electrode layer 764.

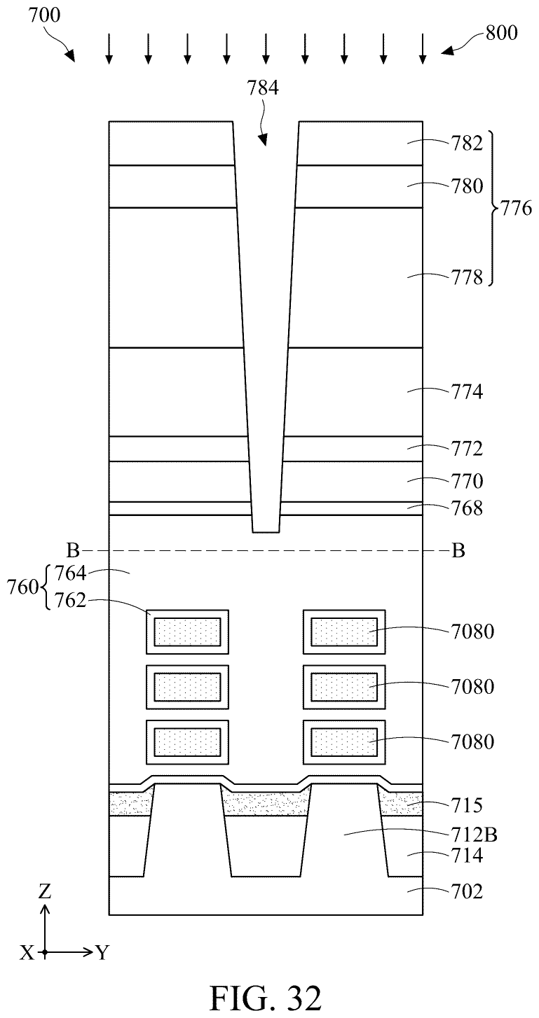

Referring to FIGS. 9 and 32, method 600 includes a block 636 where a threshold voltage (Vt) tuning dopant 800 is introduced into the gate electrode layer 764 through the gate via opening 784. The introduction of the Vt tuning dopant 800 may include an implantation process or a soaking process. The Vt tuning dopant 800 may include fluorine, oxygen, hydrogen, nitrogen, or a combination thereof. In one example, the Vt tuning dopant 800 is fluorine, and fluorine atoms are introduced to the gate electrode layer 764 by an implantation process at a temperature between about 30° C. and about 90° C. for between about 10 seconds and about 200 seconds. In another example, the Vt tuning dopant 800 is fluorine, and fluorine atoms are introduced to the gate electrode layer 764 by soaking the WIP structure 700 in a fluorine containing gas (e.g., F₂ and/or NF₃) for about 4 seconds to about 15 minutes at a temperature between about 25° C. and about 550° C. Subsequently, an annealing is performed to accelerate the diffusion of the Vt tuning dopant 800 into the WFM layer of the gate electrode layer 764. In one example, the annealing is a thermal annealing at a temperature between about 200° C. and about 400° C. The Vt tuning dopant 800 may be further driven into the gate dielectric layer 762 after the annealing. The Vt tuning dopant 800 increases the threshold voltage of the transistors, such as the pass-gate transistors PG-1 and PG-2 in FIGS. 5-8. After the introduction of the Vt tuning dopant 800, an ashing process and/or an etching process may be performed to remove the tri-layer resist layer 776.

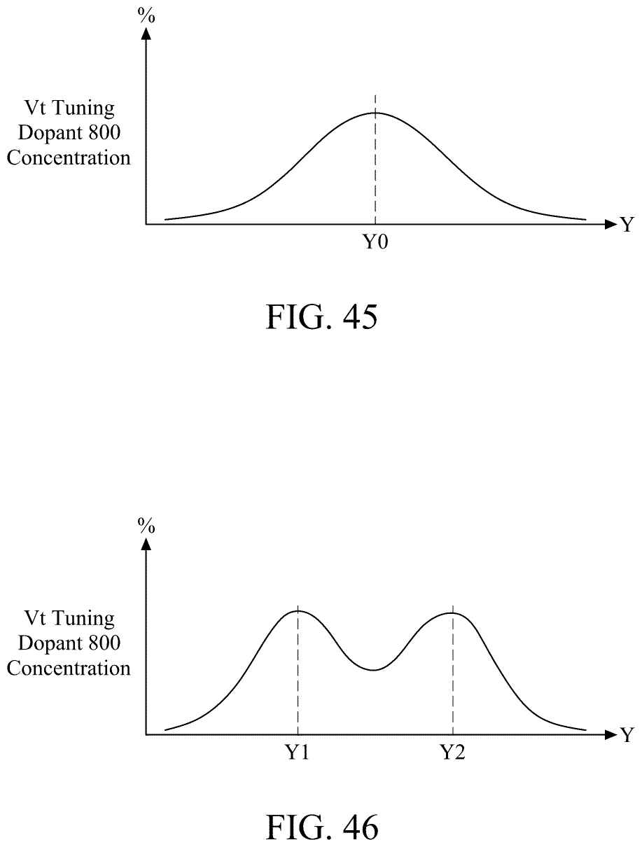

Since the Vt tuning dopant 800 is introduced through the bottom of the gate via opening 784 and diffused to other portions of the gate electrode layer 764, a concentration of the Vt tuning dopant 800 peaks at a position adjacent to the bottom of the gate via opening 784 and decreases with distance from the bottom of the gate via opening 784 in both the horizontal direction (along the Y axis) and the vertical direction (along the Z axis). A concentration plot along the B-B line in FIG. 32, which is measured at a top portion of the gate electrode layer 764, is depicted in FIG. 45. In some embodiments, the Vt tuning dopant 800 has a peak concentration at about 5% atomic percentage directly under the gate via opening 784 (Y0 on the Y axis) and gradually decreases to zero along the Y axis away from the gate via opening 784.

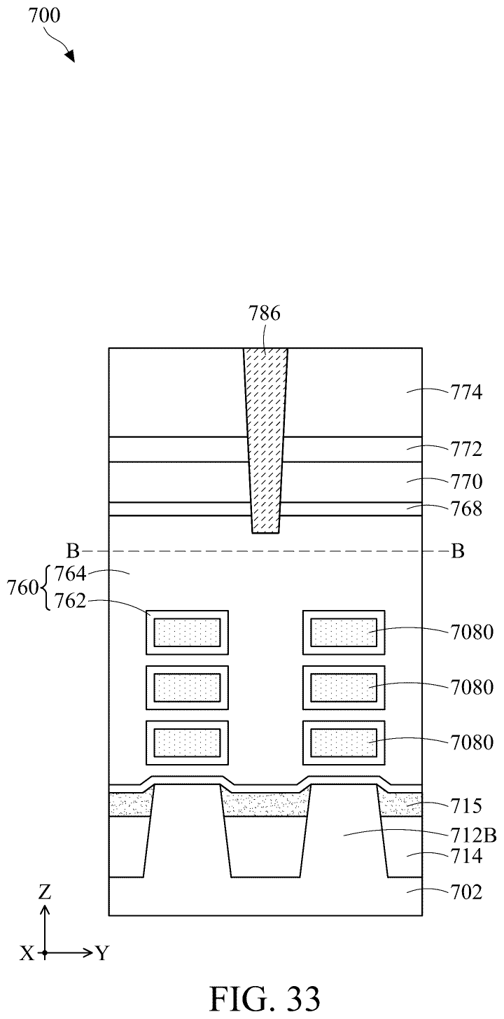

Referring to FIGS. 9 and 33, method 600 includes a block 638 where a frontside gate via 786 is formed in the gate via opening 784. In some implementations, the frontside gate via 786 functions as the frontside gate via 360A or 360L in the layout 500-1 as depicted in FIG. 5. In some embodiments, the frontside gate via 786 is formed by filling the gate via opening 784 with one or more conductive materials and subsequently removing excessive conductive materials from the frontside of the WIP structure 700 in a planarization process. The frontside gate via 786 may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be formed by CVD, PVD, ALD, plating, or other suitable processes. In some embodiments, the conductive material in forming the frontside gate via 786 is fluorine-free, such as fluorine-free tungsten. In some alternative embodiments, method 600 may optionally skip block 636 but use fluorine-containing conductive material, such as fluorine-containing tungsten, in forming the frontside gate via 786 at block 638. In this scenario, method 600 at block 638 may further perform an anneal after the forming of the frontside gate via 786 to diffuse fluorine atoms from fluorine-containing tungsten into the gate electrode layer 764 underneath to increase the threshold voltage of the transistors. The concentration plot along the B-B line in FIG. 33 is similar to the one depicted in FIG. 45.

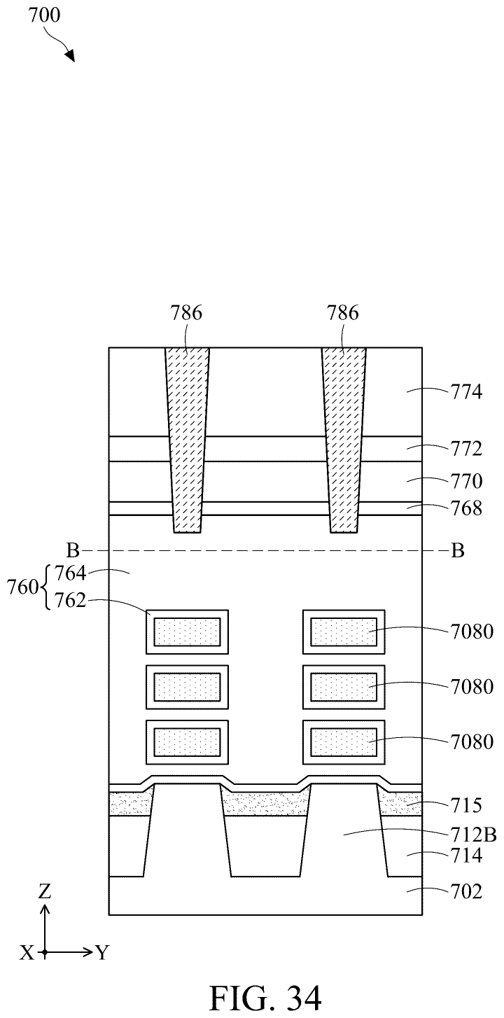

In some alternative embodiments, such as discussed above with reference to the layout 500-2 as depicted in FIG. 6, method 600 may form two frontside gate vias 786 on each of the pass-gate transistors. In some implementations, the frontside gate vias 786 may function as the frontside gate vias 360A or 360L in the layout 500-2 as depicted in FIG. 6. The resultant WIP structure 700 and the Vt tuning dopant concentration along the B-B line are illustrated in FIGS. 34 and FIG. 46, respectively. Notable, the concentration plot in FIG. 46 has two peaks, corresponding to the positions of the two frontside gate vias 786 (Y1 and Y2 at the Y axis). In the following figures, the manufacturing operations after the structure shown in FIG. 33 is formed are explained. However, the same operations can be applied to the structure shown in FIG. 34.

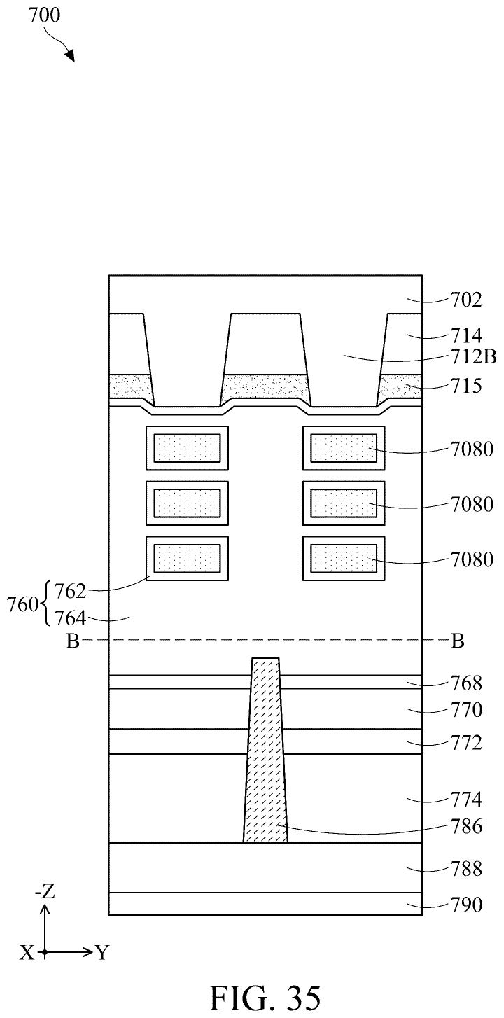

Referring to FIGS. 9 and 35, method 600 includes a block 640 where the frontside multilayer interconnect structure FMLI is completed by forming remaining higher interconnect layers 788 and thereafter the WIP structure 700 is flipped upside down by attaching the frontside of the WIP device 700 to a carrier 790. This makes the WIP structure 700 accessible from the backside of the WIP structure 700 for further processing. Method 600 at block 640 may use any suitable attaching processes, such as direct bonding, hybrid bonding, using adhesive, or other bonding methods. The carrier 790 may be a silicon wafer in some embodiments. In FIG. 35 and following figures, the “Z” direction points from the backside of the WIP structure 700 to the frontside of the WIP structure 700, while the “-Z” direction points from the frontside of the WIP structure 700 to the backside of the WIP structure 700.

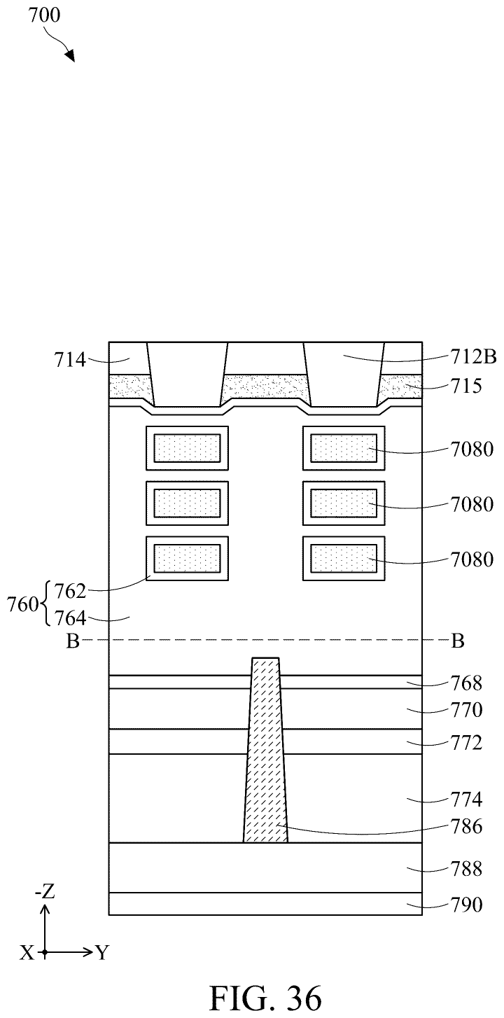

Referring to FIGS. 9 and 36, method 600 includes a block 642 where the WIP structure 700 is thinned down from the backside until the STI feature 714 is exposed from the backside of the WIP structure 700. The thinning process may include a mechanical grinding process and/or a chemical thinning process. A substantial amount of substrate material may be first removed from the substrate 702 during a mechanical grinding process. Afterwards, a chemical thinning process may apply an etching chemical to the backside of the substrate 702 to further thin down the substrate 702.

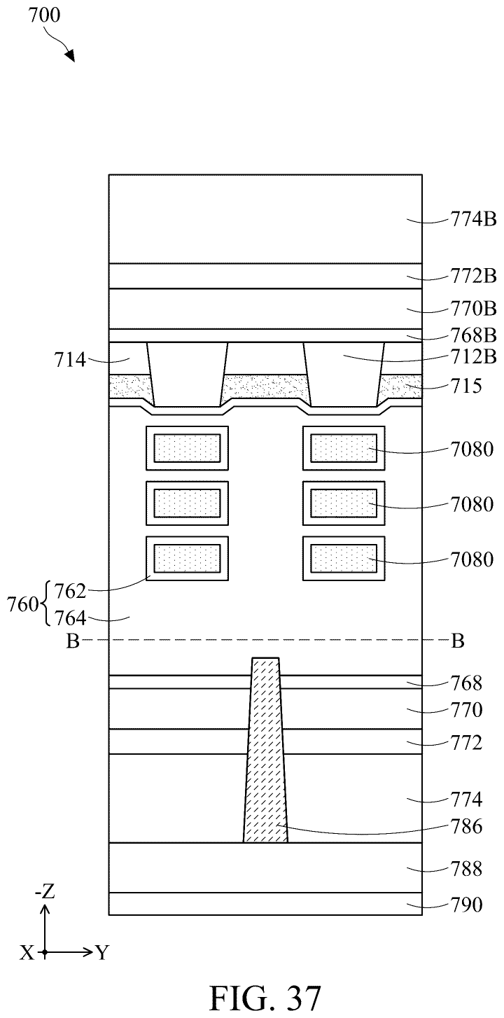

Referring to FIGS. 9 and 37, method 600 includes a block 644 where one or more backside dielectric layers as part of a backside multilayer interconnect structure BMLI are formed on the backside of the STI feature 714 and the base fin structure 712B. In the illustrated embodiment, a backside ESL 768B is deposited on the backside of the WIP structure 700, a backside ILD 770B is deposited over the backside ESL 768B, a backside ESL 772B is deposited over the backside ILD 770B, and a backside ILD 774B is deposited over the backside ESL 772B. Each of the backside ESLs 768B and 772B may comprise silicon carbide, silicon oxynitride, silicon carbo-nitride, or the like, and formed by CVD, PVD, ALD, or other suitable deposition processes; each of the backside ILDs 770B and 774B may comprise a material selected from PSG, BSG, PBSG, FSG, TEOS, or other non-porous low-k dielectric materials, and formed by flowable CVD, PE-CVD, LP-CVD, spin-on coating, or other suitable deposition processes.

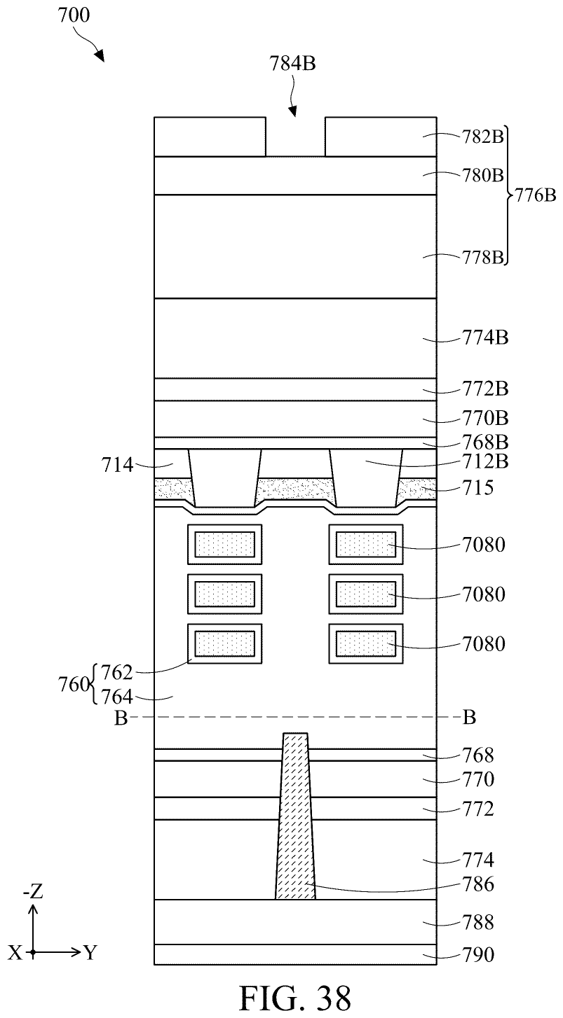

Referring to FIGS. 9 and 38-40, method 600 includes a block 646 where a backside tri-layer resist layer 776B is formed over the backside ILD 774B and patterned to form a backside gate via opening 784B. As shown in FIG. 38, the backside tri-layer resist layer 776B includes a bottom layer 778B, a middle layer 780B, and an upper layer 782B. The bottom layer 778B may be a bottom anti-reflective coating (BARC). The bottom layer 778B may include organic materials. The middle layer 780B may be formed from or include an inorganic material, which may be a nitride (such as silicon nitride), an oxynitride (such as silicon oxynitride), an oxide (such as silicon oxide), or the like. The upper layer 782B is a photosensitive material. The middle layer 780B has a high etching selectivity relative to the upper layer 782B and the bottom layer 778B. As a result, the upper layer 782B is used as an etching mask for the patterning of the middle layer 780B, and the middle layer 780B is used as an etching mask for the patterning of the bottom layer 778B. In some embodiments, the resist layer formed over the backside ILD 774B may be another type of photoresist, such as a single-layer photoresist, a bi-layer photoresist, or the like.

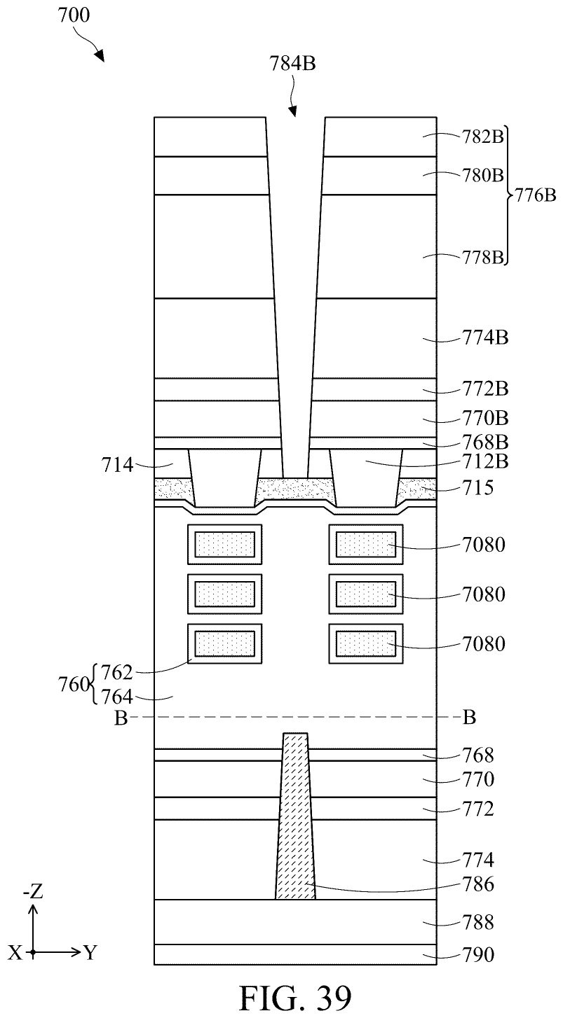

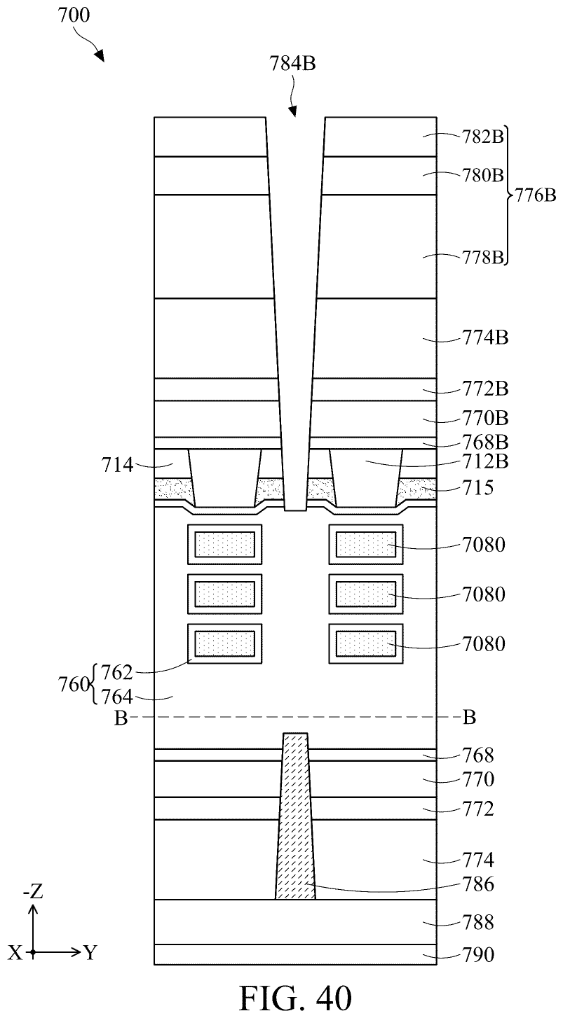

At block 646, the upper layer 782B is patterned using any suitable photolithography technique to form an opening therein, as shown in FIG. 38. As an example of patterning the upper layer 782B, the upper layer 782B may be exposed to a radiation beam including an UV or an excimer laser such as a 248 nm beam from a Krypton Fluoride (KrF) excimer laser, a 193 nm beam from an Argon Fluoride (ArF) excimer laser, or a 157 nm beam from a F₂ excimer laser. Exposure of the photosensitive material may be performed using an immersion lithography system to increase resolution and decrease the minimum achievable pitch. A bake or cure operation may be performed to harden the upper layer 782B, and a developer may be used to remove either the exposed or unexposed portions of the upper layer 782B depending on whether a positive or negative resist is used. Subsequently, the opening defined in the upper layer 782B is transferred to the underneath layers using one or more suitable etching processes, as shown in FIG. 39. The extended opening is referred to as the backside gate via opening 784B. The gate via opening 784 is extended to the hard mask layer 715 by etching through the middle layer 780B, bottom layer 778B, backside ILD 774B, backside ESL 772B, backside ILD 770B, and backside ESL 768B using one or more suitable etching processes. The hard mask layer 715 protects the gate electrode layer 764 from being directly etched. Subsequently, one or more separate etching processes with suitable etchant targeting at the hard mask layer 715 are performed to open the hard mask layer 715, as shown in FIG. 40. The separate etching processes also extend the backside gate via opening 784B through the gate dielectric layer 762 and expose the gate electrode layer 764. Furthermore, the separate etching process may over-etch into the gate electrode layer 764, such that the backside gate via opening 784B extends to a position above (along Z direction) a bottom surface of the gate electrode layer 764.

Referring to FIGS. 9 and 41, method 600 includes a block 648 where a threshold voltage (Vt) tuning dopant 900 is introduced into the gate electrode layer 764 through the backside gate via opening 784B. The introduction of the Vt tuning dopant 900 may include an implantation process or a soaking process. The Vt tuning dopant 900 may include fluorine, oxygen, hydrogen, nitrogen, or a combination thereof. The Vt tuning dopant 900 may be the same as the Vt tuning dopant 800. Alternatively, the Vt tuning dopant 900 may be a different species from the Vt tuning dopant 800. Further, the Vt tuning dopant 900 may have the same or different doses from the Vt tuning dopant 800, depending on device performance needs. For example, the dose of the Vt tuning dopant 900 may be less than the dose of the Vt tuning dopant 800, as the doping from the backside of the WIP structure 700 provides a shorter distance for the Vt tuning dopant 900 to travel into the WFM layer of the gate electrode layer 764. In one example, the Vt tuning dopant 900 is fluorine, and fluorine atoms are introduced to the gate electrode layer 764 by an implantation process at a temperature between about 30° C. and about 90° C. for between about 10 seconds and about 200 seconds. In another example, the Vt tuning dopant 900 is fluorine, and fluorine atoms are introduced to the gate electrode layer 764 by soaking the WIP structure 700 in a fluorine containing gas (e.g., F₂ and/or NF₃) for about 4 seconds to about 15 minutes at a temperature between about 25° C. and about 550° C. Subsequently, an annealing is performed to accelerate the diffusion of the Vt tuning dopant 900 into the WFM layer of the gate electrode layer 764. In one example, the annealing is a thermal annealing at a temperature between about 200° C. and about 400° C. The Vt tuning dopant 900 may be further driven into the gate dielectric layer 762 after the annealing. The Vt tuning dopant 900 increases the threshold voltage of the transistors, such as the pass-gate transistors PG-1 and PG-2 in FIGS. 5-8. After the introduction of the Vt tuning dopant 900, an ashing process and/or an etching process may be performed to remove the backside tri-layer resist layer 776B.

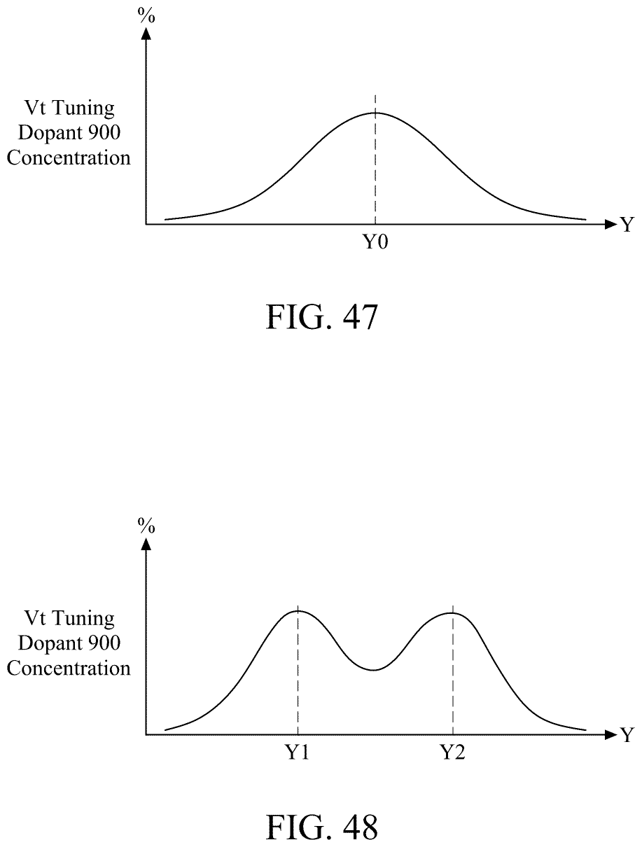

Since the Vt tuning dopant 900 is introduced through the bottom of the backside gate via opening 784B and diffused to other portions of the gate electrode layer 764, a concentration of the Vt tuning dopant 900 peaks at a position adjacent to the bottom of the backside gate via opening 784B and decreases with distance from the bottom of the backside gate via opening 784B in both the horizontal direction (along the Y axis) and the vertical direction (along the Z axis). A concentration plot along the C-C line in FIG. 41, which is measured at a bottom portion of the gate electrode layer 764, is depicted in FIG. 47. In some embodiments, the Vt tuning dopant 900 has a peak concentration at about 5% atomic percentage directly under the backside gate via opening 784B (Y0 on the Y axis) and gradually decreases to zero along the Y axis away from the backside gate via opening 784B. Further, in some embodiments, the peak of the Vt tuning dopant 900 may be higher than the peak of the Vt tuning dopant 800, depending on device performance requirements.

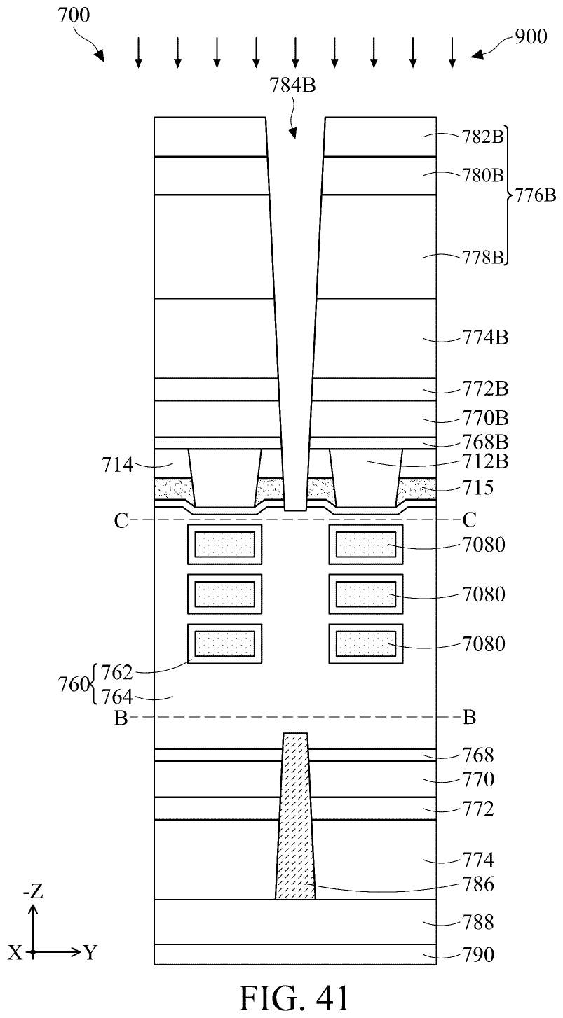

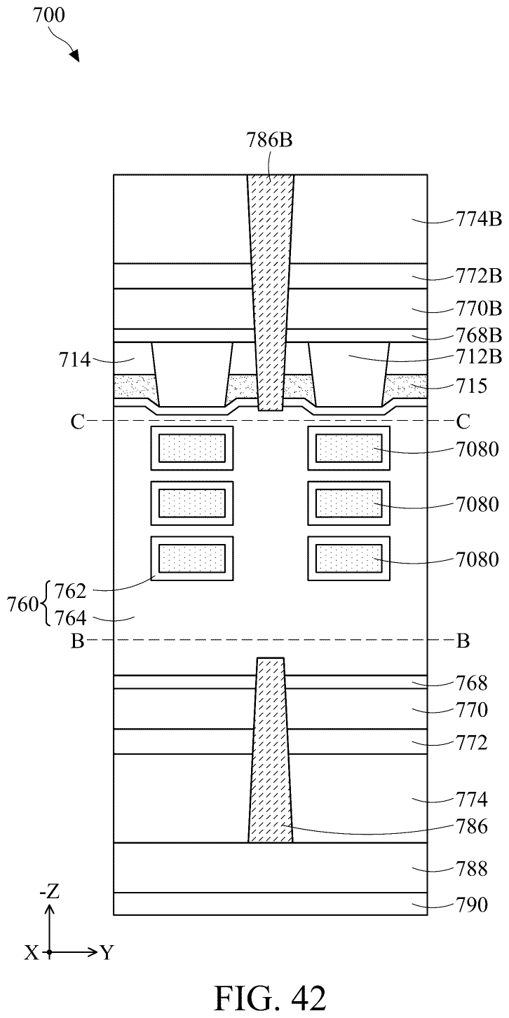

Referring to FIGS. 9 and 42, method 600 includes a block 650 where a backside gate via 786B is formed in the backside gate via opening 784B. In some implementations, the backside gate via 786B functions as the backside gate via B360A or B360L in the layout 500-3 as depicted in FIG. 7. In some embodiments, the backside gate via 786B is formed by filling the backside gate via opening 784B with one or more conductive materials and subsequently removing excessive conductive materials from the backside of the WIP structure 700 in a planarization process. The backside gate via 786B may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be formed by CVD, PVD, ALD, plating, or other suitable processes. In some embodiments, the conductive material in forming the backside gate via 786B is fluorine-free, such as fluorine-free tungsten. In some alternative embodiments, method 600 may optionally skip block 648 but use fluorine-containing conductive material, such as fluorine-containing tungsten, in forming the backside gate via 786B at block 650. In this scenario, method 600 at block 650 may further perform an anneal after the forming of the backside gate via 786B to diffuse the fluorine from the fluorine-containing tungsten into the gate electrode layer 764 underneath to increase the threshold voltage of the transistors. The concentration plot along the C-C line in FIG. 42 is similar to the one depicted in FIG. 47.

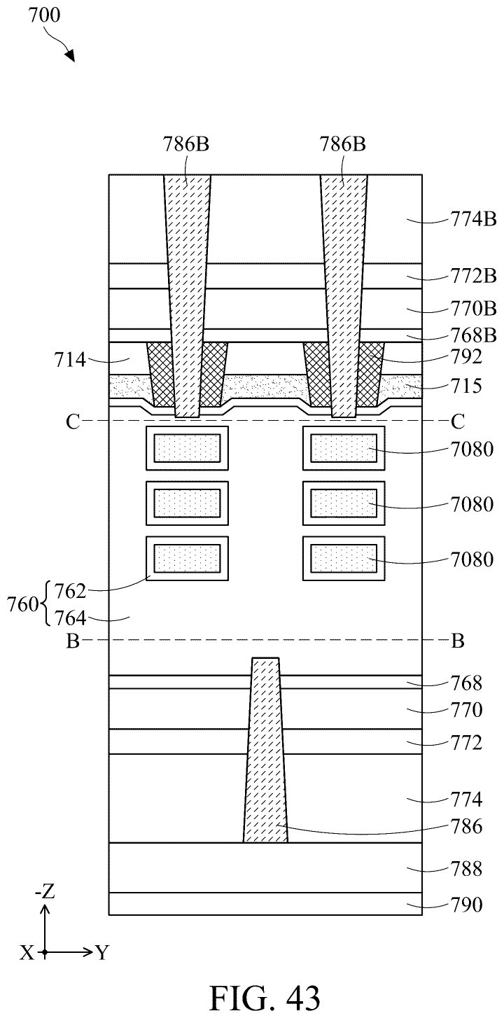

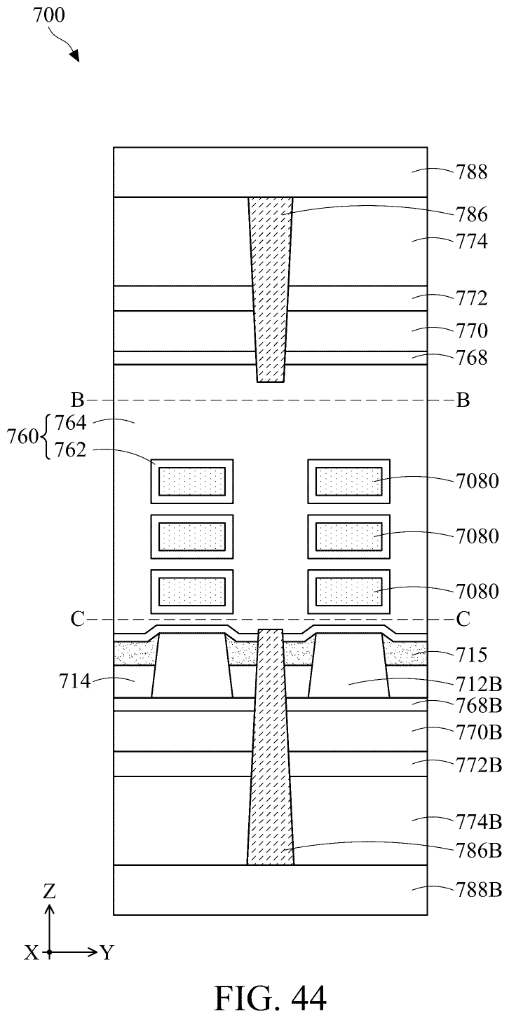

In some alternative embodiments, such as discussed above with reference to the layout 500-4 as depicted in FIG. 8, method 600 may form two backside gate vias 786B under each of the pass-gate transistor. In some implementations, the backside gate vias 786B function as the backside gate vias B360A or B360L in the layout 500-4 as depicted in FIG. 8. The resultant WIP structure 700 and the Vt tuning dopant concentration along the C-C line are illustrated in FIGS. 43 and FIG. 48, respectively. Notably, in this scenario, the base fin structure 712B may be removed by an etching process and replaced by a backside dielectric feature 792 prior to the deposition of the backside ESL 768B, such that the backside gate vias 786B extend through the backside dielectric feature 792 and the gate dielectric layer 762 and further into the gate electrode layer 764. The concentration plot in FIG. 48 has two peaks, corresponding to the positions of the two backside gate vias 786B (Y1 and Y2 at the Y axis). In the following FIG. 44, the manufacturing operations after the structure shown in FIG. 42 is formed are explained. However, the same operations can be applied to the structure shown in FIG. 43.

Reference is now made to FIG. 44. Method 600 may continue to finish the backside multilayer interconnect structure BMLI by forming remaining lower interconnect layers 788B and thereafter the WIP structure 700 may be flipped back to finish other processes in the manufacturing flow, including forming passivation layers, forming bond pads, dicing, and packaging. The illustrated embodiment as shown in FIG. 44 has one frontside gate via 786 shared by the two transistors and one backside gate via 786B shared by the two transistors with the Vt tuning dopant concentration in the top portion of the gate electrode layer (e.g., B-B line) as shown in FIG. 45 and the Vt tuning dopant concentration in the bottom portion of the gate electrode layer (e.g., C-C line) as shown in FIG. 47. As discussed above with respect to various embodiments in FIGS. 5-8, the WIP structure 700 may have one or two frontside gate vias 786 and independently one or two backside gate vias 786B, or the WIP structure 700 may have no frontside gate vias but one or two backside gate vias 786B, or the WIP structure 700 may have one or two frontside gate vias but no backside gate vias 786B. Still further, the Vt tuning dopant may be doped only from the frontside of the WIP structure 700, only from the backside of the WIP structure 700, or from both the frontside and backside of the WIP structure 700 depending on device performance requirements.

The SRAM cells and the corresponding layouts illustrated in various exemplary embodiments of the present disclosure provide frontside gate vias and backside gate vias as an opportunity to further adjust threshold voltages of the pass-gate transistors in the SRAM cells to achieve a larger beta ratio. The increased beta ratio enlarges read operational window and improves memory performance. Further, embodiments of the present disclosure, without altering the front-end-of-line (FEOL) operations in the manufacturing flow, can be readily integrated into existing semiconductor manufacturing processes.

In one exemplary aspect, the present disclosure is directed to a method of manufacturing a semiconductor device. The method includes forming over a substrate a stack that includes channel layers interleaved by sacrificial layers, patterning the stack to form a fin-shaped structure, forming a dummy gate stack over a channel region of the fin-shaped structure, depositing a gate spacer layer over the dummy gate stack, after the depositing of the gate spacer layer, recessing a source/drain region of the fin-shaped structure, selectively removing the sacrificial layers in the channel region to release the channel layers as channel members, depositing a dummy layer in space between the channel members, selectively and partially recessing the dummy layer to form inner spacer recesses, forming inner spacers in the inner spacer recesses, forming a source/drain feature over the source/drain region, removing the dummy gate stack, removing the dummy layer, forming a gate structure to wrap around each of the channel members, the gate structure including a gate dielectric layer and a gate electrode layer, depositing a backside dielectric layer on a backside of the semiconductor device, patterning the backside dielectric layer to form a backside gate via opening directly under the gate structure, doping a threshold voltage tuning dopant into the gate electrode layer of the gate structure through the backside gate via opening, and after the doping of the threshold voltage tuning dopant, forming a backside gate via in the backside gate via opening. In some embodiments, the semiconductor device is a memory device including at least a first memory cell and a second memory cell abutting the first memory cell, and the gate structure is part of a first pass-gate transistor in the first memory cell. In some embodiments, the gate structure is shared with a second pass-gate transistor in the second memory cell. In some embodiments, the threshold voltage tuning dopant is selected from fluorine, oxygen, hydrogen, or nitrogen. In some embodiments, a peak of a concentration of the threshold voltage tuning dopant is positioned directly above the backside gate via. In some embodiments, the method further includes performing an annealing to diffuse the threshold voltage tuning dopant into a work function metal layer of the gate electrode layer. In some embodiments, the method further includes depositing an isolation feature on sidewalls of the fin-shaped structure, depositing a hard mask layer over the isolation feature, extending the backside gate via opening through the isolation feature in a first etching process, and extending the backside gate via opening through the hard mask layer in a second etching process different from the first etching process. In some embodiments, the method further includes after the extending of the backside gate via opening through the hard mask layer, extending the backside gate via opening through the gate dielectric layer to expose the gate electrode layer of the gate structure. In some embodiments, the method further includes depositing a frontside dielectric layer on a frontside of the semiconductor device, patterning the frontside dielectric layer to form a frontside gate via opening directly above the gate structure, and forming a frontside gate via in the frontside gate via opening. In some embodiments, the method further includes prior to the forming of the frontside gate via, diffusing the threshold voltage tuning dopant into the gate electrode layer of the gate structure through the frontside gate via opening.

In another exemplary aspect, the present disclosure is directed to a method of manufacturing a semiconductor device. The method includes forming first and second active regions protruding from a substrate, depositing a first gate across the first and second active regions to form a first transistor and a second transistor, depositing a second gate across the first active region to form a third transistor, depositing a third gate across the second active region in forming a fourth transistor, depositing a dielectric layer covering the first, second, and third gates, forming a gate via opening through the dielectric layer and exposing the first gate, doping a threshold voltage tuning dopant into the first gate through the gate via opening, and forming a gate via in the gate via opening. In some embodiments, the first transistor is a pass-gate transistor of a first memory cell, the second transistor is a pull-down transistor of the first memory cell, the third transistor is a pass-gate transistor of a second memory cell abutting the first memory cell, and the fourth transistor is a pull-down transistor of the second memory cell. In some embodiments, after the forming of the gate via, either of the third and fourth transistors is free of a gate via electrically coupled thereto. In some embodiments, the dielectric layer is deposited on a frontside of the semiconductor device, and the gate via opening exposes a top surface of the first gate. In some embodiments, the dielectric layer is deposited on a backside of the semiconductor device, and the gate via opening exposes a bottom surface of the first gate. In some embodiments, the gate via opening is a first gate via opening and the gate via is a first gate via, and the method further includes forming a second gate via opening through the dielectric layer and exposing the first gate, doping a threshold voltage tuning dopant into the first gate through the second gate via opening, and forming a second gate via in the second gate via opening. In some embodiments, after the doping of the threshold voltage tuning dopant, a threshold voltage of the first and second transistors is higher than that of the third and fourth transistors.

In yet another exemplary aspect, the present disclosure is directed to a memory device. The memory device includes a plurality of first nanostructures vertically stacked, a plurality of second nanostructures vertically stacked and laterally spaced apart from the first nanostructures, a gate structure wrapping around each of the first and second nanostructures, a gate via electrically coupled to the gate structure, and a threshold voltage tuning dopant distributed in a gate electrode layer of the gate structure, wherein a peak of a concentration of the threshold voltage tuning dopant is vertically aligned with the gate via. In some embodiments, the gate via is a first gate via, and the memory device further includes a second gate via electrically coupled to the gate structure. The first gate via is disposed on a bottom surface of the gate structure, and the second gate via is disposed on a top surface of the gate structure. In some embodiments, the gate via is a first gate via, and the memory device further includes a second gate via electrically coupled to the gate structure. The first and second gate vias are disposed on a same side of the gate structure, the peak of the concentration of the threshold voltage tuning dopant is a first peak, and a second peak of the concentration of the threshold voltage tuning dopant is vertically aligned with the second gate via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of forming a semiconductor device, comprising:
forming a stack over a substrate, the stack including channel layers interleaved by sacrificial layers;
patterning the stack to form a fin-shaped structure;
depositing an isolation structure on sidewalls of the fin-shaped structure, a top surface of the isolation structure being non-planar;
forming a dummy gate stack over a channel region of the fin-shaped structure;
depositing a gate spacer layer over the dummy gate stack;
recessing a source/drain region of the fin-shaped structure;
removing the sacrificial layers in the channel region to release the channel layers as channel members;
depositing a dummy layer in space between the channel members;
forming a source/drain feature over the source/drain region;
removing the dummy gate stack;
removing the dummy layer;
forming a gate structure to wrap around at least one of the channel members in forming a transistor, the gate structure including a gate dielectric layer and a gate electrode layer over the gate dielectric layer, the gate electrode layer including a titanium-containing material;
depositing a backside dielectric layer on a backside of the semiconductor device;
patterning the backside dielectric layer to form a backside gate via opening directly under the gate structure;
doping a dopant into the gate electrode layer of the gate structure through the backside gate via opening; and
after the doping of the dopant, forming a backside gate via in the backside gate via opening.

2. The method of claim 1, wherein the doping of the dopant alters a threshold voltage of the transistor.

3. The method of claim 1, wherein the dopant is selected from fluorine, oxygen, hydrogen, or nitrogen.

4. The method of claim 1, further comprising:
etching through the isolation structure from a bottom surface of the isolation structure, such that the backside gate via opening extends through the isolation structure.

5. The method of claim 4, further comprising:
etching through the gate dielectric layer from a bottom surface of the gate dielectric layer, such that the backside gate via opening extends through the gate dielectric layer.

6. The method of claim 1, wherein a peak of a concentration of the dopant is positioned directly above the backside gate via.

7. The method of claim 1, further comprising:
performing an annealing to diffuse the dopant into the gate electrode layer.

8. The method of claim 1, further comprising:
depositing a frontside dielectric layer on a frontside of the semiconductor device;
patterning the frontside dielectric layer to form a frontside gate via opening directly above the gate structure; and
forming a frontside gate via in the frontside gate via opening.

9. The method of claim 8, further comprising:
prior to the forming of the frontside gate via, doping the dopant into the gate electrode layer of the gate structure through the frontside gate via opening.

10. The method of claim 1, wherein the semiconductor device includes a first cell and a second cell abutting the first cell, and the gate structure is a common gate structure shared by the first and second cells.

11. A method, comprising:
forming first and second active regions protruding from a substrate;
depositing a gate structure across the first and second active regions to form a first transistor and a second transistor, the gate structure including a titanium-containing material;
depositing a backside dielectric layer under the first and second active region;
forming a backside gate via opening through the backside dielectric layer and exposing the gate structure;
doping a threshold voltage tuning dopant into the gate structure through the backside gate via opening; and
forming a backside gate via in the backside gate via opening.

12. The method of claim 11, further comprising:
depositing a frontside dielectric layer over the gate structure;
forming a frontside gate via opening through the frontside dielectric layer and exposing the gate structure; and
forming a frontside gate via in the frontside gate via opening.

13. The method of claim 12, further comprising:
prior to the forming of the frontside gate via, doping the threshold voltage tuning dopant into the gate structure through the frontside gate via opening.

14. The method of claim 11, wherein the backside gate via is position laterally between the first and second active regions.

15. The method of claim 11, wherein the backside gate via opening is a first backside gate via opening and the backside gate via is a first backside gate via, the method further comprising:
forming a second backside gate via opening through the backside dielectric layer and exposing the gate structure; and
forming a second backside gate via in the second backside gate via opening.

16. the method of claim 15, wherein a concentration of the threshold voltage tuning dopant in the gate structure has first and second peaks corresponding to locations of the first and second backside gate vias, respectively.

17. A semiconductor device, comprising:
a plurality of first nanostructures vertically stacked;
a plurality of second nanostructures vertically stacked and laterally spaced apart from the first nanostructures;
a gate structure wrapping around at least one of the first nanostructures and at least one of the second nanostructures, the gate structure comprising a gate dielectric layer and a gate electrode over the gate dielectric layer;
a gate spacer extending along a sidewall of the gate structure, a dielectric constant of the gate dielectric layer being greater than a dielectric constant of the gate spacer;
a gate via electrically coupled to the gate electrode of the gate structure; and
a dopant distributed in the gate electrode of the gate structure, wherein a peak of a concentration of the dopant in the gate electrode is vertically aligned with the gate via.

18. The semiconductor device of claim 17, wherein the gate via is a frontside gate via disposed over the gate electrode of the gate structure.

19. The semiconductor device of claim 17, wherein the gate via is a backside gate via disposed under the gate electrode of the gate structure.

20. The semiconductor device of claim 17, wherein the dopant is selected from fluorine, oxygen, hydrogen, or nitrogen.
